(19) United States
(12) Patent Application Publication
(10) Pub. No.: US 2026/0093177 A1
(43) Pub. Date: Apr. 2, 2026

(54) PATTERNING PROCESS

(71) Applicant: SHIN-ETSU CHEMICAL CO., LTD., Tokyo (JP)

(72) Inventors: Hidenori YAMAGUCHI, Joetsu-shi (JP); Yuki SUDA, Joetsu-shi (JP); Kazunori MAEDA, Joetsu-shi (JP); Seiichiro TACHIBANA, Joetsu-shi (JP)

(73) Assignee: SHIN-ETSU CHEMICAL CO., LTD., Tokyo (JP)

(21) Appl. No.: 19/338,782

(22) Filed: Sep. 24, 2025

(30) Foreign Application Priority Data
Oct. 2, 2024 (JP) 2024-173346

(51) Int. Cl. G03F 7/039; G03F 7/00; G03F 7/40

(52) U.S. Cl. CPC G03F 7/0392; G03F 7/40; G03F 7/70025

(57) ABSTRACT

A patterning process including: forming a multilayer on a substrate for processing; forming a resist upper layer film using a positive chemically-amplified resist composition for ArF excimer; removing the acid-labile group in an exposed portion of the resist upper layer film by exposure and post-exposure bake; performing a higher temperature hard bake for a shorter time than post-exposure bake allowing the removed acid-labile group to volatilize out of the resist upper layer film and a number difference of carbon atoms between an unexposed and exposed portion; removing the resist upper layer film in the exposed portion with a gas plasma containing oxygen by dry development pattern separation; and transferring the resist upper layer film pattern to the multilayer underneath by etching. The patterning process obtains a fine pattern having a narrow pitch by dry development using a (meth)acrylic polymer usable for ArF patterning as the main skeleton and without silylation.

### TECHNICAL FIELD

The present invention relates to a patterning process.

### BACKGROUND ART

To achieve higher integration of semiconductor devices, fine processing technology has progressed. Lithography technology and dry etching technology are important manufacturing process technologies that support fine processing, and resist materials used here are important process materials that determine processing dimensions.

For fine processing of DRAM (Dynamic Random Access Memory) circuits used in most-advanced semiconductor devices, such as HBM (High Bandwidth Memory), ArF immersion technology with an exposure wavelength of 193 nm is still frequently used, and in particular, regarding narrow pitch patterns generally having a 40-nm line and space (80-nm pattern pitch) or narrower, so-called double patterning technology, where the pattern pitch is halved by a combination of multilayer process technology in lithography and CVD film formation technology, is frequently used.

In a case where a line-and-space pattern that is to have a narrow pitch of 40 nm or less in the end is formed, an ArF positive chemically amplified resist, in which exposed portions are dissolved in an aqueous alkaline solution to form a pattern, is often used as a resist material. One reason for this is that resolution performance is better compared to ArF negative resists, in which an organic solvent is used to allow exposed portions to remain.

However, such high performance has come to be required that pattern edge roughness cannot be ignored even in ArF positive resists, which have high resolution. It is known that one cause of this pattern edge roughness is the effect of the action of a TMAH (tetramethylammonium hydroxide) developer, being an aqueous alkaline solution, on a resist to make the resist swell, and the distortion and wiggling of a resist pattern that occur in a drying process after development rinsing.

In manufacturers that manufacture resist materials, to reduce the pattern edge roughness of ArF resists, polymer compositions in which there is little effect of swelling in an aqueous solution are being developed, low-diffusion photo-acid catalyst materials for enhancing the resolution of positive types are being developed, and the components constituting the resist materials and conditions of use are being optimized.

Meanwhile, in fields other than ArF immersion exposure, such as lithography and fine processing technology, patterning by dry development has been studied to avoid the problem of pattern swelling, being a cause of pattern edge roughness, due to wet development.

As an example where a dry development process is applied, reported are methods for performing patterning by dry development by the silylation of chemically amplified positive resist compositions, such as styrene and novolak-based compositions (Patent Documents 1, 2).

There is also a report of a dry development method for a non-chemically amplified resist, where negative-positive inversion is performed by controlling the temperature of the substrate to be processed to be subjected to dry development (Patent Document 3).

There is also a report regarding a resist material that applies to exposure wavelengths of 300 to 500 nm, the resist material making use of the fact that a phenolic hydroxy group is substituted with an acid-labile group and the removal of the acid-labile group causes a difference in etching rate between exposed portions and unexposed portions in dry development where oxygen gas is contained (Patent Document 4).

Furthermore, there is also a report of using, for pattern separation, the difference in film thickness between exposed portions and unexposed portions that occurs due to the ideal volume change of a chemically amplified resist between before and after exposure (Patent Document 5).

### CITATION LIST

### Patent Literature

Patent Document 1: JP H07-022304 A
Patent Document 2: JP 2004-103926 A
Patent Document 3: JP H07-161607 A
Patent Document 4: JP 2018-136536 A
Patent Document 5: JP 2023-157346 A

### SUMMARY OF INVENTION

### Technical Problem

However, although silylation technology is effective as a method for achieving selectivity in dry etching, special equipment for silylation needs to be introduced, and in addition, the process is complicated and the risk of defects accompanying increase in steps is increased.

Meanwhile, the report of the resist patterning with negative-positive inversion is a report of research concerning non-chemically amplified resists of polyvinyl phenol and cresol novolak. There is a description regarding PMMA, but it is difficult to use, for current mass production technology that requires high productivity, a method in which the main chain of a PMMA polymer is directly decomposed with an energy beam and used for patterning, due to the problem of insufficient etching resistance and the problem of insufficient exposure sensitivity.

Meanwhile, regarding the study of dry development using the ideal volume change between before and after the exposure, it is reported that a dry development pattern can be formed without the addition of a special resist and step for obtaining a pattern if a difference of 45% or more in film thickness can be achieved between unexposed portions and exposed portions. However, if a base polymer is substituted with a high substitution rate (e. g. protection with an acid decomposition group at a protection rate of 100%) to achieve a great ideal volume change, a large exposure dose is needed to achieve a predetermined high removal reaction. Alternatively, a high-temperature PEB is needed instead of the exposure dose to promote the deprotection. However, a high-temperature PEB causes increase in acid diffusion length, and causes a problem of degradation in fine processing workability.

The present invention has been invented in view of the above-described circumstances. An object of the present invention is to provide a patterning process that makes it possible to obtain a fine pattern having a narrow pitch by dry development using a (meth)acrylic polymer usable for ArF patterning as the main skeleton and without silylation.

### Solution to Problem

To achieve the object, the present invention provides a patterning process comprising the steps of:
forming a multilayer on a substrate to be processed;
forming a resist upper layer film by using a positive chemically-amplified resist composition for ArF excimer containing, at least, a base polymer having a (meth)acrylic structure substituted with an acid-labile group, a photo-acid generator, a quencher having a function of controlling acid diffusion, and an organic solvent;
removing the acid-labile group in an exposed portion of the resist upper layer film by exposure and a post-exposure bake;
performing a hard bake at a higher temperature and for a shorter time than the post-exposure bake to allow the removed acid-labile group to volatilize out of the resist upper layer film and cause a difference in a number of carbon atoms between an unexposed portion and the exposed portion;
removing the resist upper layer film in the exposed portion with a gas plasma containing oxygen by dry development to separate a pattern; and
transferring the pattern of the resist upper layer film to the multilayer underneath by etching.

According to such a patterning process, it is possible to obtain a fine pattern having a narrow pitch by dry development using a (meth)acrylic polymer usable for ArF patterning as the main skeleton and without silylation.

In the present invention, the base polymer preferably has a (meth)acrylic structure in which a rate of substitution with the acid-labile group is 80% to 100% and the acid-labile group has 4 to 9 carbon atoms.

By using a resist composition containing such a base polymer, a predetermined dry development selectivity between unexposed portions and exposed portions can be achieved.

In the present invention, it is possible to use, as the base polymer, one that does not have a lactone structure.

Even when a resist composition containing such a base polymer is used, the exposure, the subsequent baking, the dry development, and the subsequent transfer to the multilayer underneath by dry etching can be performed favorably.

In the present invention, it is preferable that the post-exposure bake is performed at 80° C. to 120° C. for 40 seconds to 120 seconds, and the hard bake is performed at 130° C. or higher for less than 40 seconds.

By performing the post-exposure bake and the hard bake with such a temperature and time, the deprotection reaction of the acid-labile group and the volatilization action can progress with more certainty.

In the present invention, it is preferable that the resist composition further contains a surfactant that functions as a top coat for ArF immersion exposure, or the patterning process further comprises a step of applying and forming a top coat before the exposure.

In the present invention, pattern separation by dry development is possible even when a top coat is applied and formed, and when the resist composition contains a surfactant, the step of applying and forming the top coat can be omitted.

### Advantageous Effects of Invention

As described above, according to the inventive patterning process, wet development with an aqueous alkaline solution is not performed, and therefore, pattern roughness due to the swelling effect of the resist at the time of development and pattern roughness due to the distortion and wiggling of the resist pattern that occurs during drying after development rinsing do not occur. Therefore, a favorable pattern having little resist line edge roughness can be obtained.

Furthermore, since the dry development does not require silylation, there are no additional special equipment for silylation or complication of processes, and there is no risk of increase in process defects due to increase in the number of steps. Advantageous effects that lead to the improvement of critical dimension uniformity in DRAM products and the reduction of pattern defects caused by roughness can be expected.

### BRIEF DESCRIPTION OF DRAWINGS

FIG. 1 is an explanatory diagram of an example (water repellent-containing resist film for immersion) of the inventive patterning process.

FIG. 2 is and explanatory diagram of a different example (immersion top coat film formation) of the inventive patterning process.

### DESCRIPTION OF EMBODIMENTS

As described above, there have been demands for the development of a patterning process that makes it possible to obtain a fine pattern having a narrow pitch by dry development using a (meth)acrylic polymer usable for ArF patterning as the main skeleton and without silylation.

The present inventors have earnestly studied the problems and found out that it is possible to use, as a patterning process, a method of: (A) forming a resist upper layer film by using a resist composition containing, at least, a base polymer having a (meth)acrylic structure substituted with an acid-labile group, a photo-acid generator, a quencher that controls acid diffusion, and an organic solvent; (B) allowing the acid-labile group to undergo a removal reaction by a post-exposure bake (PEB); (C) volatilizing the removed acid-labile group by performing a hard bake at a high temperature and for a short time to reduce the carbon content in the exposed portion; and (D) performing dry development with a gas plasma containing oxygen gas to obtain a predetermined separated pattern of the resist upper layer film. Thus, the present invention has been completed.

That is, the present invention is a patterning process comprising the steps of:
forming a multilayer on a substrate to be processed;
forming a resist upper layer film by using a positive chemically-amplified resist composition for ArF excimer containing, at least, a base polymer having a (meth)acrylic structure substituted with an acid-labile group, a photo-acid generator, a quencher having a function of controlling acid diffusion, and an organic solvent;
removing the acid-labile group in an exposed portion of the resist upper layer film by exposure and a post-exposure bake;
performing a hard bake at a higher temperature and for a shorter time than the post-exposure bake to allow the removed acid-labile group to volatilize out of the resist upper layer film and cause a difference in a number of carbon atoms between an unexposed portion and the exposed portion;
removing the resist upper layer film in the exposed portion with a gas plasma containing oxygen by dry development to separate a pattern; and
transferring the pattern of the resist upper layer film to the multilayer underneath by etching.

Hereinafter, the present invention will be described in detail, but the present invention is not limited thereto.

### [Positive Chemically-Amplified Resist Composition for ArF Excimer]

The positive chemically-amplified resist composition for ArF excimer used in the inventive patterning process contains: a base polymer having a (meth)acrylic structure substituted with an acid-labile group; a photo-acid generator; a quencher having a function of controlling acid diffusion; and an organic solvent. In addition, other components can be contained as necessary. Hereinafter, each component will be described in detail.

### [Base Polymer]

The base polymer contained in the above-described resist composition has a (meth)acrylic structure substituted with an acid-labile group. The structure is not particularly limited, but one containing a repeating unit-a1, represented by the following general formula (a1), or a repeating unit-a2, represented by the following general formula (a2), is preferable.

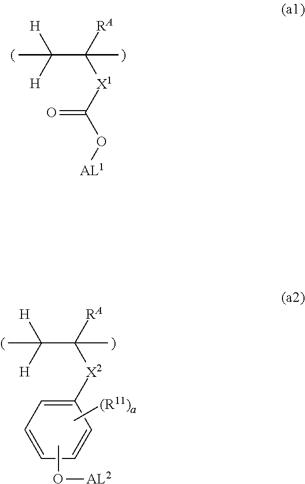

In the general formulae (a1) and (a2), each R^{A} independently represents a hydrogen atom, a fluorine atom, a methyl group, or a trifluoromethyl group. X¹ represents a single bond, a phenylene group, a naphthylene group, or (main chain)-C(═O)—O—X¹¹—, and X¹¹ represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring. X² represents a single bond or (main chain)-C(═O)—O—. AL¹ and AL² each independently represent an acid-labile group.

The number of atoms in the acid-labile group is not particularly limited as long as the acid-labile group is volatilized out of the resist upper layer film by the hard bake, but is preferably 9 or less, more preferably 4 or more and 9 or less, and further preferably 8 or 9.

Meanwhile, the number of oxygen atoms in the acid-labile group to be removed in the PEB and volatilized in the hard bake is preferably 3 or less, further preferably 2 or less.

Meanwhile, the smaller number of hydrogen atoms in the acid-labile group to be volatilized after the hard bake, the better, and the number is preferably 22 or less, more preferably 18 or less.

Meanwhile, in the general formula (a2), R¹¹ represents a hydrocarbyl group having 1 to 20 carbon atoms and optionally containing a heteroatom. The hydrocarbyl group may be saturated or unsaturated, and may be linear, branched, or cyclic. “a” represents an integer of 0 to 4, preferably 0 or 1.

Examples of structures where the X¹ in the general formula (a1) is varied include the following, but are not limited thereto. Note that, in the following formulae, R^{A} and AL¹ are as defined above.

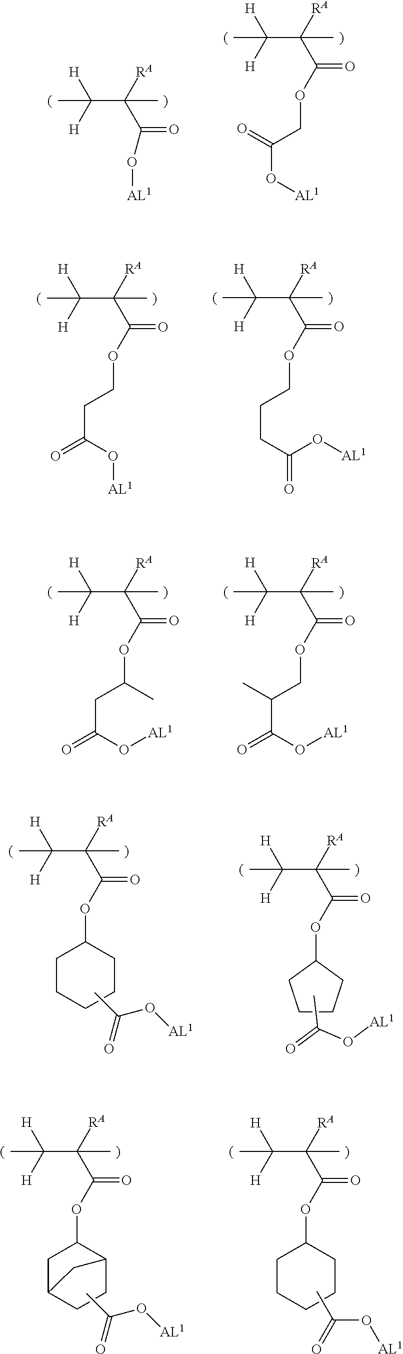

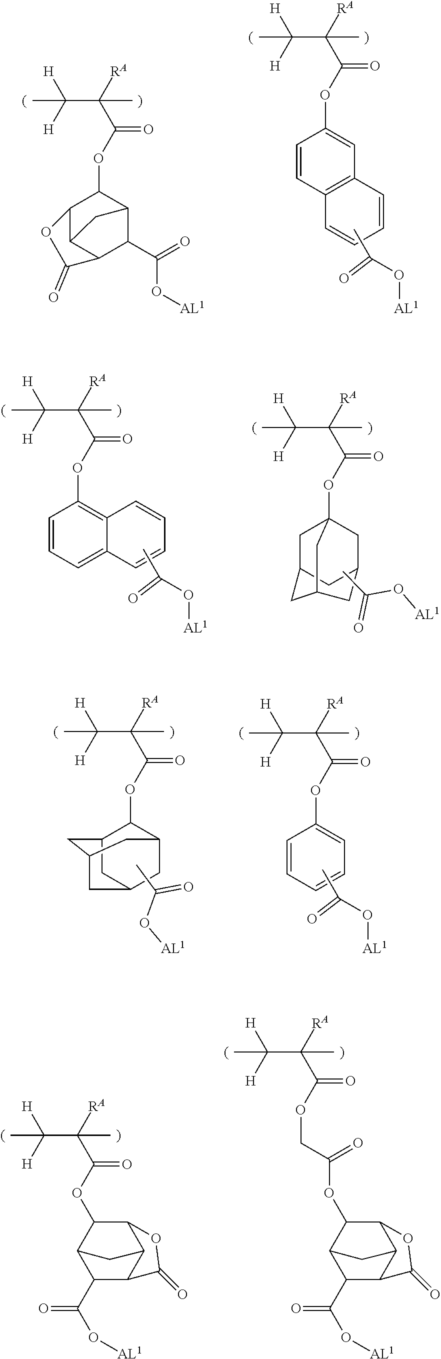

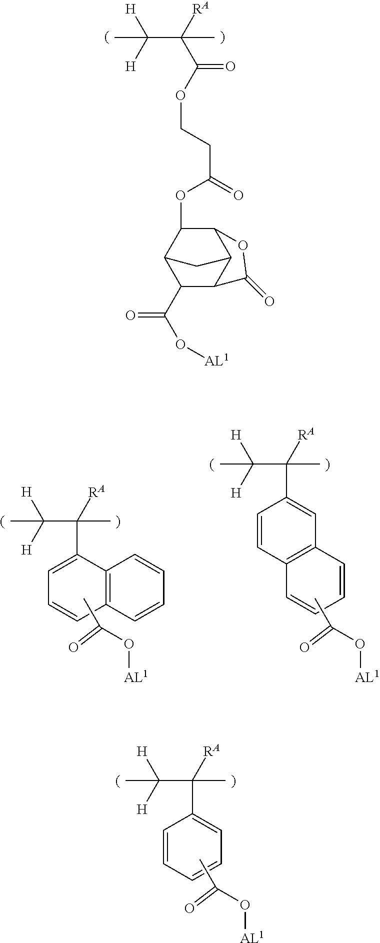

A base polymer containing the repeating unit-a1 is decomposed by the action of an acid and generates a carboxy group, and becomes alkali-soluble.

Preferable examples of the acid-labile group represented by AL¹ and AL² include groups selected from the following general formulae (L1) to (L4), tertiary hydrocarbyl groups having 4 to 9, preferably 8 or 9 carbon atoms, and saturated hydrocarbyl groups having 4 to 9 carbon atoms and containing a carbonyl group, an ether bond, or an ester bond.

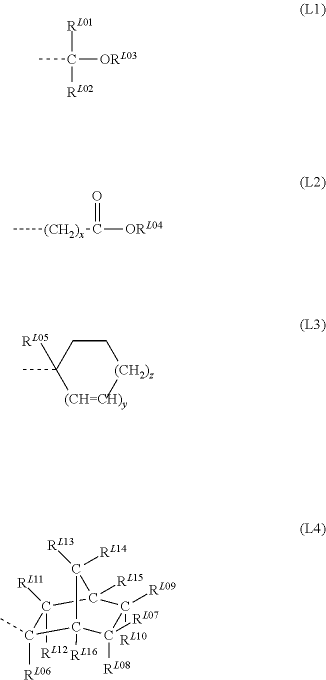

In the general formula (L1), R^{L01} and R^{L02} each represent a hydrogen atom or a saturated hydrocarbyl group having 1 to 8 carbon atoms. The saturated hydrocarbyl group may be linear, branched, or cyclic, and specific examples thereof include: alkyl groups, such as a methyl group, an ethyl group, a propyl group, an isopropyl group, an n-butyl group, a sec-butyl group, a tert-butyl group, an n-octyl group, and a 2-ethylhexyl group; and cyclic saturated hydrocarbyl groups such as a cyclopentyl group, a cyclohexyl group, and a norbornyl group.

In the general formula (L1), R^{L03} represents a hydrocarbyl group having 1 to 8 carbon atoms, and optionally contains a heteroatom. The hydrocarbyl group may be saturated or unsaturated, and may be linear, branched, or cyclic, and is preferably a saturated hydrocarbyl group. In addition, part or all of the hydrogen atoms of the saturated hydrocarbyl group may be substituted with a hydroxy group, a saturated hydrocarbyloxy group, an oxo group, an amino group, a saturated hydrocarbylamino group, etc., and part of the —CH₂— constituting the saturated hydrocarbyl group may be substituted with a group containing a heteroatom such as an oxygen atom. Examples of the saturated hydrocarbyl group include those given as examples of the saturated hydrocarbyl group represented by R^{L01} and R^{L02}, Furthermore, examples of the substituted saturated hydrocarbyl group include the following groups. Note that a broken line in the formulae represents an attachment point.

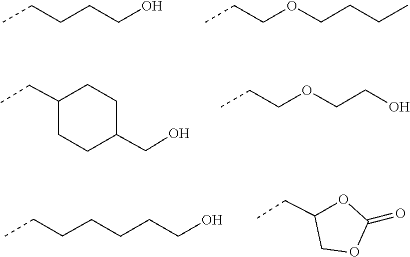

Any two of R^{L01}, R^{L02}, and R^{L03} may be bonded to each other to form a ring together with the carbon atom or the carbon atom and the oxygen atom bonded thereto. When a ring is formed, the two out of R^{L01}, R^{L02}, and R^{L03} involved in the formation of the ring preferably each have 1 to 8 carbon atoms.

In the general formula (L2), R^{L04} represents a tertiary hydrocarbyl group, a saturated hydrocarbyl group having 4 to 9 carbon atoms and containing a carbonyl group, an ether bond, or an ester bond, or a group represented by the general formula (L1). “x” represents an integer of 0 to 6.

The tertiary hydrocarbyl group represented by R^{L04} may be branched or cyclic, and specific examples thereof include a tert-butyl group, a tert-pentyl group, a 1,1-diethylpropyl group, a 2-cyclopentylpropan-2-yl group, a 2-cyclohexylpropan-2-yl group, a 1-ethylcyclopentyl group, a 1-butylcyclopentyl group, a 1-ethylcyclohexyl group, a 1-ethyl-2-cyclopentenyl group, and a 1-ethyl-2-cyclohexenyl group. Examples of the saturated hydrocarbyl group containing a carbonyl group, an ether bond, or an ester bond include a 3-oxocyclohexyl group, a 4-methyl-2-oxooxan-4-yl group, and a 5-methyl-2-oxooxolan-5-yl group.

In the general formula (L3), R^{L05} represents a saturated hydrocarbyl group having 1 to 6 carbon atoms and optionally being substituted. The saturated hydrocarbyl group, optionally being substituted, may be linear, branched, or cyclic, and specific examples thereof include: alkyl groups, such as a methyl group, an ethyl group, a propyl group, an isopropyl group, an n-butyl group, a sec-butyl group, a tert-butyl group, a tert-pentyl group, an n-pentyl group, and an n-hexyl group; cyclic saturated hydrocarbyl groups, such as a cyclopentyl group and a cyclohexyl group; these groups, having part or all of the hydrogen atoms thereof substituted with a hydroxy group, a saturated hydrocarbyloxy group, a carboxy group, a saturated hydrocarbylcarbonyl group, an oxo group, an amino group, a saturated hydrocarbylamino group, a cyano group, a mercapto group, a saturated hydrocarbylthio group, a sulfo group, etc.

In the general formula (L3), “y” represents 0 or 1, and “z” represents an integer of 0 to 3.

In the general formula (L4), R^{L06} represents a saturated hydrocarbyl group having 1 or 2 carbon atoms and optionally being substituted. Meanwhile, in the general formula (L4), R^{L07} to R^{L16} each independently represent a hydrogen atom or a hydrocarbyl group having 1 or 2 carbon atoms and optionally being substituted. The hydrocarbyl group may be saturated or unsaturated, and examples of the hydrocarbyl group include a methyl group and an ethyl group.

Among the acid-labile groups represented by the general formula (L1), examples of linear or branched groups include the following groups, but are not limited thereto. A broken line in the formulae represents an attachment point.

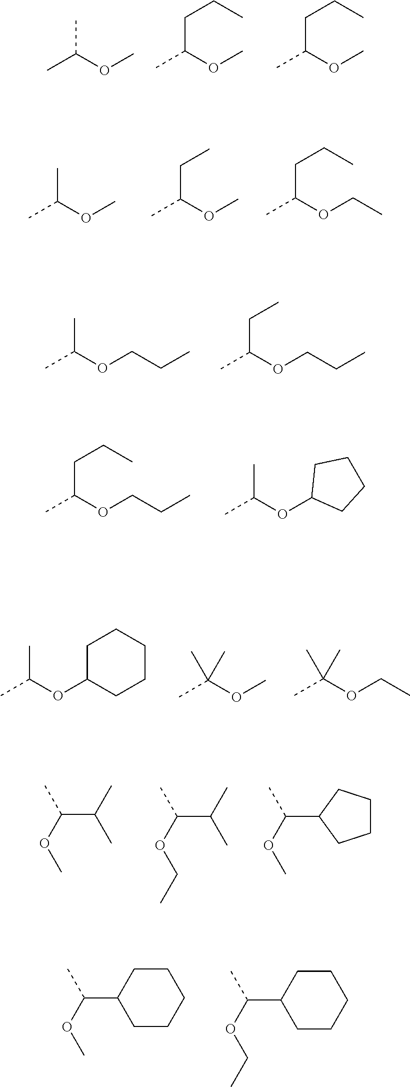

Among the acid-labile groups represented by the general formula (L1), examples of cyclic groups include a tetrahydrofuran-2-yl group, a 2-methyltetrahydrofuran-2-yl group, a tetrahydropyran-2-yl group, and a 2-methyltetrahydropyran-2-yl group.

Examples of the acid-labile group represented by the general formula (L2) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1,1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, and a 2-tetrahydrofuranyloxycarbonylmethyl group.

Examples of the acid-labile group represented by the general formula (L3) include a 1-methylcyclopentyl group, a 1-ethylcyclopentyl group, a 1-n-propylcyclopentyl group, a 1-isopropylcyclopentyl group, a 1-n-butylcyclopentyl group, a 1-sec-butylcyclopentyl group, a 1-methylcyclohexyl group, a 1-ethylcyclohexyl group, a 3-methyl-1-cyclopenten-3-yl group, a 3-ethyl-1-cyclopenten-3-yl group, a 3-methyl-1-cyclohexen-3-yl group, and a 3-ethyl-1-cyclohexen-3-yl group.

As the acid-labile group represented by the general formula (L4), a group represented by the following general formula (L4-1) is particularly preferable.

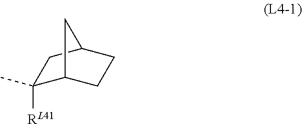

In the general formula (L4-1), a broken line represents an attachment point and bond direction. Each R^{L41} independently represents a hydrocarbyl group having 1 or 2 carbon atoms. The hydrocarbyl group may be saturated or unsaturated. Examples of the hydrocarbyl group include a methyl group and an ethyl group.

Examples of the acid-labile group represented by the general formula (L4) include the groups shown below, but are not limited thereto. Note that, in the formulae, a broken line represents an attachment point.

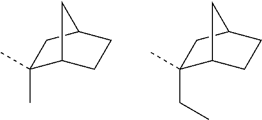

Among the acid-labile groups represented by AL¹ and AL², examples of the tertiary hydrocarbyl group having 4 to 9 carbon atoms and the saturated hydrocarbyl group having 4 to 9 carbon atoms and containing a carbonyl group, an ether bond, or an ester bond each include those given as examples in the description of R^{L04}

Examples of the repeating unit-a1 include the following, but are not limited thereto. Note that, in the following formulae, R^{A} is as defined above.

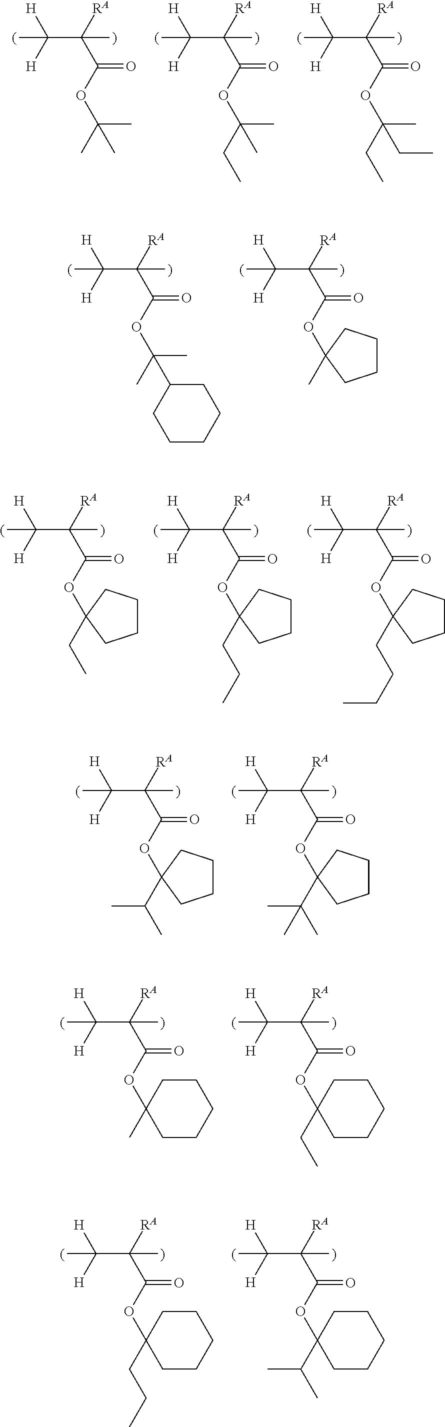

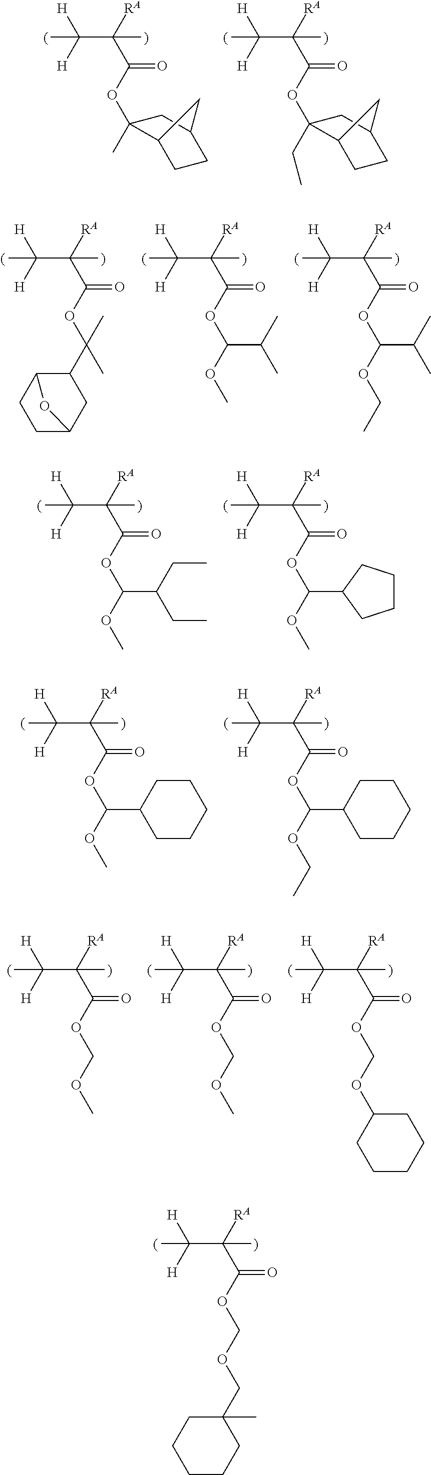

Note that, although these specific examples are cases where X¹ is a single bond, combinations with similar acid-labile groups are also possible in cases where X¹ is not a single bond. Specific examples where X¹ is not a single bond are as described above.

A base polymer containing the repeating unit-a2 is decomposed by the action of an acid and generates a hydroxy group, and becomes alkali-soluble in the same manner as with the repeating unit-a1.

Examples of the repeating unit-a2 include the following, but are not limited thereto. Note that, in the following formulae, R^{A} is as defined above.

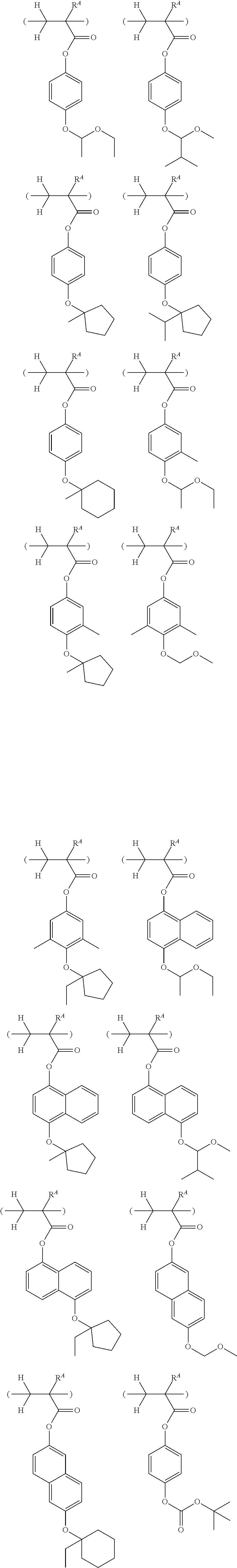

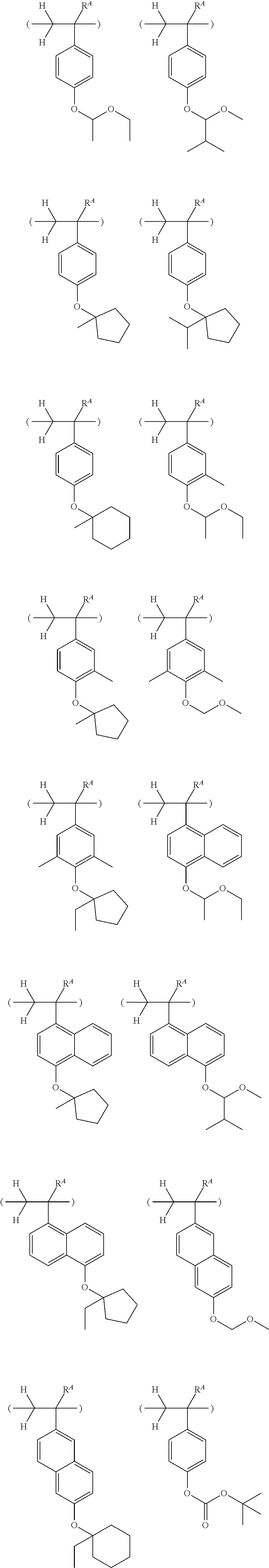

Furthermore, as the base polymer, it is also possible to use one that does not have a lactone structure. The exposure, the subsequent baking, the dry development, and the subsequent transfer to the multilayer underneath by dry etching can also be performed favorably when such a base polymer is used.

The etching selectivity between unexposed portions and exposed portions in dry development is highest when substitution with an acid-labile group is 100%.

To achieve a predetermined dry development selectivity between unexposed portions and exposed portions, a base polymer having a (meth)acrylic structure in which the rate of substitution with the acid-labile group (the rate of protection of the base polymer) is 80% to 100% is preferable as the base polymer.

That is, it is preferable to use, as the base polymer, one that has a (meth)acrylic structure in which a rate of substitution with the acid-labile group is 80% to 100% and the acid-labile group has 4 to 9 carbon atoms.

The rate of substitution with the acid-labile group is a value determined using NMR.

Meanwhile, the molecular weight Mw of the base polymer is not particularly limited, but is preferably 1,000 to 50,000. Note that the molecular weight Mw is the weight-average molecular weight, and is a value measured by gel permeation chromatography (GPC) using tetrahydrofuran as an eluent and polystyrene as a standard substance.

Examples of methods for synthesizing the base polymer include a method of subjecting the monomers to give the repeating units described above to heat polymerization in an organic solvent to which a polymerization initiator has been added.

Examples of the organic solvent used in the polymerization reaction include toluene, benzene, THF, diethyl ether, and dioxane. Examples of the polymerization initiator include 2,2′-azobisisobutyronitrile (AIBN), 2,2′-azobis(2,4-dimethylvaleronitrile), dimethyl-2,2′-azobis (2-methylpropionate), benzoyl peroxide, and lauroyl peroxide. The reaction temperature is preferably 50 to 80° C. The reaction time is preferably 2 to 100 hours, more preferably 5 to 20 hours. An acid-labile group introduced into the monomer may be used as it is, or may be protected or partially protected after polymerization.

### [Photo-Acid Generator]

The photo-acid generator is not particularly limited as long as it is a compound that generates an acid on irradiation with a high-energy beam such as ultraviolet ray, deep ultraviolet ray, EB, EUV, X-ray, excimer laser beam, γ-ray, and synchrotron radiation. Examples of suitable photo-acid generators include photo-acid generator, such as sulfonium salt, iodonium salt, sulfonyldiazomethane, N-sulfonyloxydicarboxyimide, O-arylsulfonyloxime, and O-alkylsulfonyloxime. Examples of these photo-acid generators include those disclosed in paragraphs [0102] to [0113] of JP 2007-145797 A.

Examples of preferable photo-acid generators include sulfonium salts represented by the following general formula (2).

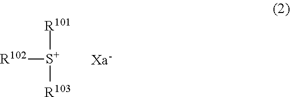

In the general formula (2), R¹⁰¹, R¹⁰², and R¹⁰³ each independently represent a hydrocarbyl group having 1 to 20 carbon atoms and optionally containing a heteroatom. The hydrocarbyl group represented by R¹⁰¹, R¹⁰², and R¹⁰³ having 1 to 20 carbon atoms may be saturated or unsaturated, and may be linear, branched, or cyclic. Specific examples thereof include: alkyl groups having 1 to 20 carbon atoms, such as a methyl group, an ethyl group, a propyl group, an isopropyl group, an n-butyl group, a sec-butyl group, a tert-butyl group, a tert-pentyl group, an n-pentyl group, an n-hexyl group, an n-octyl group, a 2-ethylhexyl group, an n-nonyl group, and an n-decyl group; cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; aryl groups, such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, a tert-butylnaphthyl group, and an anthracenyl group; and groups which are combinations of these groups. Part or all of the hydrogen atoms in these groups are optionally substituted with a group containing a heteroatom, such as an oxygen atom, a sulfur atom, a nitrogen atom, and a halogen atom. Part of the —CH₂— in these groups optionally has an intervening group containing a heteroatom, such as an oxygen atom, a sulfur atom, and a nitrogen atom. As a result, a hydroxy group, a fluorine atom, a chlorine atom, a bromine atom, an iodine atom, a cyano group, a carbonyl group, an ether bond, a thioether bond, an ester bond, a sulfonic acid ester bond, a carbonate bond, a carbamate bond, a lactone ring, a sultone ring, a carboxylic anhydride, a haloalkyl group, etc. are optionally contained.

Furthermore, R¹⁰¹ and R¹⁰² may be bonded to each other to form a ring together with the sulfur atom bonded thereto. In this case, as the ring, those having the following structures are preferable. Note that a broken line in the formulae represents an attachment point to R¹⁰³.

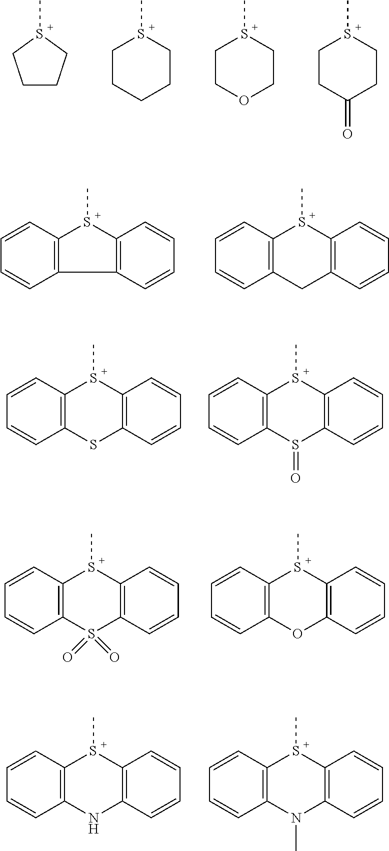

Examples of the sulfonium cation of the sulfonium salt represented by the general formula (2) include cations such as triphenylsulfonium, 4-hydroxyphenyldiphenylsulfonium, bis(4-hydroxyphenyl)phenylsulfonium, tris(4-hydroxyphenyl)sulfonium, 4-tert-butylphenyldiphenylsulfonium, bis(4-tert-butylphenyl)phenylsulfonium, tris(4-tert-butylphenyl)sulfonium, 4-tert-butoxyphenyldiphenylsulfonium, bis(4-tert-butoxyphenyl)phenylsulfonium, tris(4-tert-butoxyphenyl)sulfonium, 3-tert-butoxyphenyldiphenylsulfonium, bis(3-tert-butoxyphenyl)phenylsulfonium, tris(3-tert-butoxyphenyl)sulfonium, 3,4-di-tert-butoxyphenyldiphenylsulfonium, bis(3,4-di-tert-butoxyphenyl)phenylsulfonium, tris(3,4-di-tert-butoxyphenyl)sulfonium, diphenyl(4-thiophenoxyphenyl)sulfonium, 4-tert-butoxycarbonylmethyloxyphenyldiphenylsulfonium, tris(4-tert-butoxycarbonylmethyloxyphenyl)sulfonium, (4-tert-butoxyphenyl)bis(4-dimethylaminophenyl)sulfonium, tris(4-dimethylaminophenyl)sulfonium, 2-naphthyldiphenylsulfonium, (4-hydroxy-3,5-dimethylphenyl)diphenylsulfonium, (4-n-hexyloxy-3,5-dimethylphenyl)diphenylsulfonium, dimethyl(2-naphthyl)sulfonium, 4-hydroxyphenyldimethylsulfonium, 4-methoxyphenyldimethylsulfonium, trimethylsulfonium, 2-oxocyclohexylcyclohexylmethylsulfonium, trinaphthylsulfonium, tribenzylsulfonium, diphenylmethylsulfonium, dimethylphenylsulfonium, 2-oxo-2-phenylethylthiacyclopentanium, diphenyl-2-thienylsulfonium, 4-n-butoxynaphthyl-1-thiacyclopentanium, 2-n-butoxynaphthyl-1-thiacyclopentanium, 4-methoxynaphthyl-1-thiacyclopentanium, 2-methoxynaphthyl-1-thiacyclopentanium.

Further examples of the sulfonium cation of the sulfonium salt represented by the general formula (2) include those represented by the following formulae. Note that, in the following formulae, Me represents a methyl group.

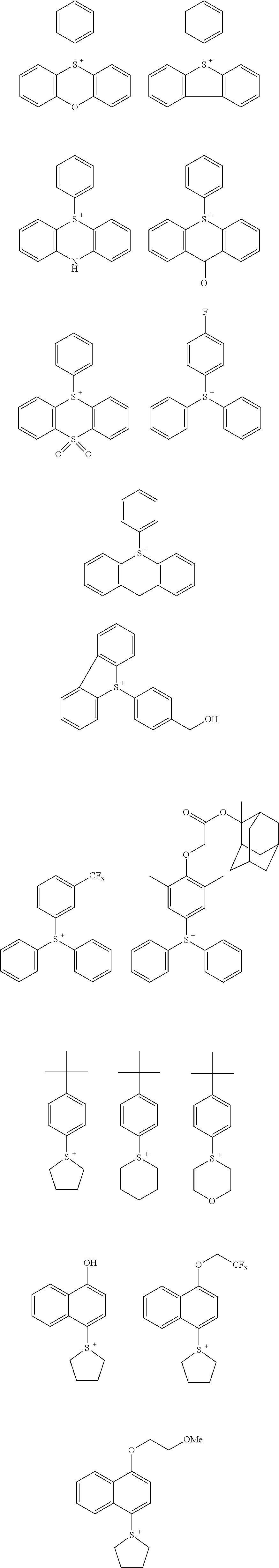

Among these, triphenylsulfonium, 4-tert-butylphenyldiphenylsulfonium, 4-tert-butoxyphenyldiphenylsulfonium, tris(4-tert-butylphenyl) sulfonium, tris(4-tert-butoxyphenyl) sulfonium, dimethylphenylsulfonium, etc. are preferable.

In the general formula (2), Xa⁻ represents an anion represented by any of the following general formulae (2A) to (2D).

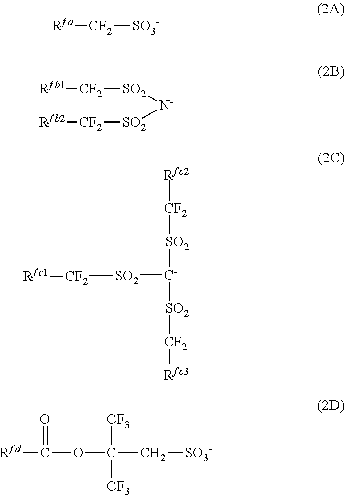

In the general formula (2A), R^{fa} represents a fluorine atom or a hydrocarbyl group having 1 to 40 carbon atoms and optionally containing a heteroatom. The hydrocarbyl group may be saturated or unsaturated, and may be linear, branched, or cyclic.

As the anion represented by the general formula (2A), an anion represented by the following general formula (2A′) is particularly preferable.

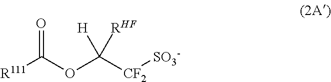

In the general formula (2A′), R^{HF} represents a hydrogen atom or a trifluoromethyl group. R¹¹¹ represents a hydrocarbyl group having 1 to 30 carbon atoms and optionally containing a heteroatom. The heteroatom is preferably an oxygen atom, a nitrogen atom, a sulfur atom, or a halogen atom, more preferably an oxygen atom. The hydrocarbyl group particularly preferably has 6 to 30 carbon atoms from the viewpoint of achieving high resolution in fine pattern formation.

The hydrocarbyl group represented by R¹¹¹ may be saturated or unsaturated, and may be linear, branched, or cyclic. Specific examples thereof include alkyl groups having 1 to 30 carbon atoms, such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; cyclic saturated hydrocarbyl groups having 3 to 30 carbon atoms, such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; unsaturated aliphatic hydrocarbyl groups having 2 to 30 carbon atoms, such as an allyl group and a 3-cyclohexenyl group; aryl groups having 6 to 30 carbon atoms, such as a phenyl group, a 1-naphthyl group, and a 2-naphthyl group; aralkyl groups having 7 to 30 carbon atoms, such as a benzyl group and a diphenylmethyl group; groups which are combinations of these groups; etc.

Furthermore, part or all of the hydrogen atoms of these groups may be substituted with a group containing a heteroatom, such as an oxygen atom, a sulfur atom, a nitrogen atom, or a halogen atom, and part of the carbon atoms of these groups may be substituted with a group containing a heteroatom such as an oxygen atom, a sulfur atom, or a nitrogen atom. The resulting hydrocarbyl group may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride, a haloalkyl group, etc. Examples of the hydrocarbyl group containing a heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

The synthesis of the sulfonium salt having the anion shown by the general formula (2A′) is described in detail in JP 2007-145797 A, JP 2008-106045 A, JP 2009-007327 A, JP 2009-258695 A, etc.

Examples of the anion represented by the general formula (2A) include nonafluorobutanesulfonate, partially fluorinated sulfonates disclosed in paragraphs [0247] to [0251] of JP 2012-189977 A, partially fluorinated sulfonates disclosed in paragraphs [0261] to [0265] of JP 2013-101271 A, and the following, but are not limited thereto. Note that, in the following formulae, Ac represents an acetyl group.

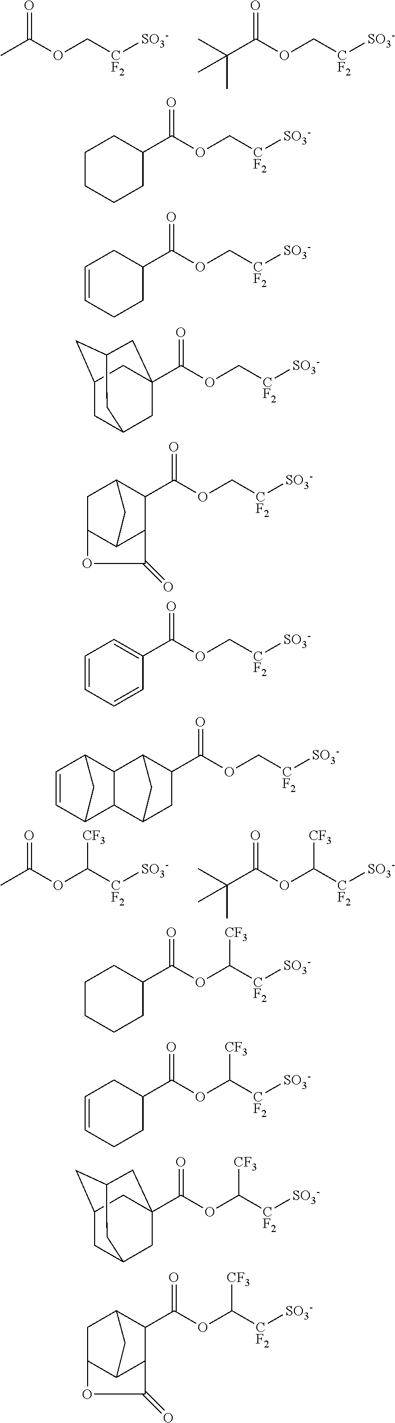

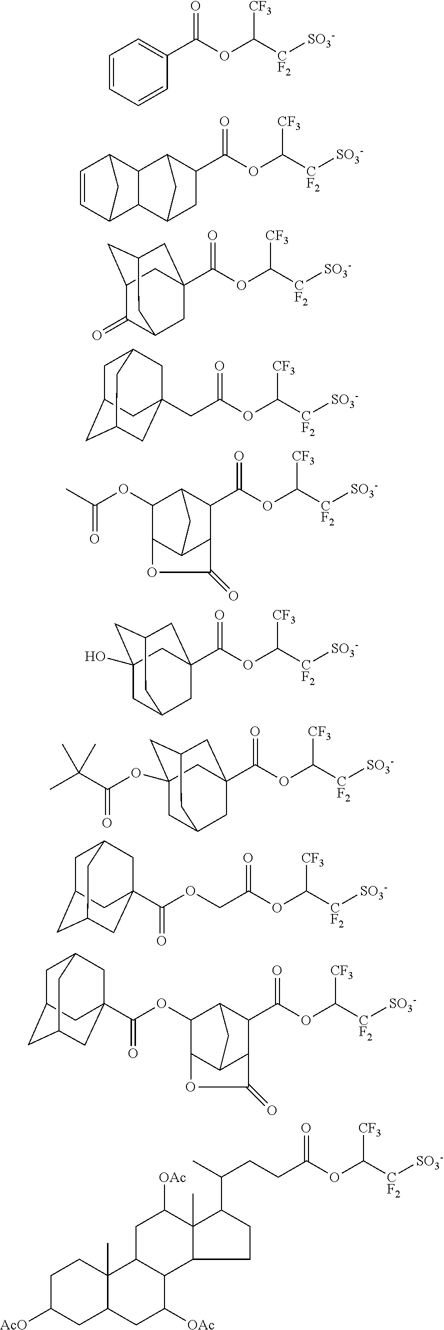

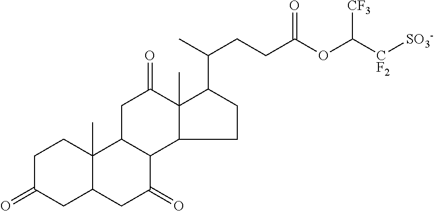

In the general formula (2B), R^{fb1} and R^{fb2} each independently represent a fluorine atom or a hydrocarbyl group having 1 to 40 carbon atoms and optionally containing a heteroatom. The hydrocarbyl group may be saturated or unsaturated, and may be linear, branched, or cyclic. Specific examples thereof include those given as examples of the hydrocarbyl group represented by the R¹¹¹ in the general formula (2A′). R^{fb1} and R^{fb2} are preferably a fluorine atom or a linear fluorinated alkyl group having 1 to 4 carbon atoms. Alternatively, R^{fb1} and R^{fb2} may bond with each other to form a ring together with the group (—CF₂—SO₂—N—SO₂—CF₂—) bonded therewith. In this event, the group obtained by R^{fb1} and R^{fb2} being bonded to each other is preferably a fluorinated ethylene group or a fluorinated propylene group.

In the general formula (2C), R^{fc1}, R^{fc2}, and R^{fc3} each independently represent a fluorine atom or a hydrocarbyl group having 1 to 40 carbon atoms and optionally containing a heteroatom. The hydrocarbyl group may be saturated or unsaturated, and may be linear, branched, or cyclic. Specific examples thereof include those given as examples of the hydrocarbyl group represented by the R¹¹¹ in the general formula (2A′). R^{fc1}, R^{fc2}, and R^{fc3} are preferably a fluorine atom or a linear fluorinated alkyl group having 1 to 4 carbon atoms. Alternatively, R^{fc1} and R^{fc2} may bond with each other to form a ring together with the group (—CF₂—SO₂—C——SO₂—CF₂—) bonded therewith. In this event, the group obtained by R^{fc1} and R^{fc2} being bonded with each other is preferably a fluorinated ethylene group or a fluorinated propylene group.

In the general formula (2D), R^{fd} represents a hydrocarbyl group having 1 to 40 carbon atoms and optionally containing a heteroatom. The hydrocarbyl group may be saturated or unsaturated, and may be linear, branched, or cyclic. Specific examples thereof include those given as examples of the hydrocarbyl group represented by the R¹¹¹ in the general formula (2A′).

The synthesis of the sulfonium salt having the anion represented by the general formula (2D) is described in detail in JP 2010-215608 A.

Examples of the anion represented by the general formula (2D) include the following, but are not limited thereto.

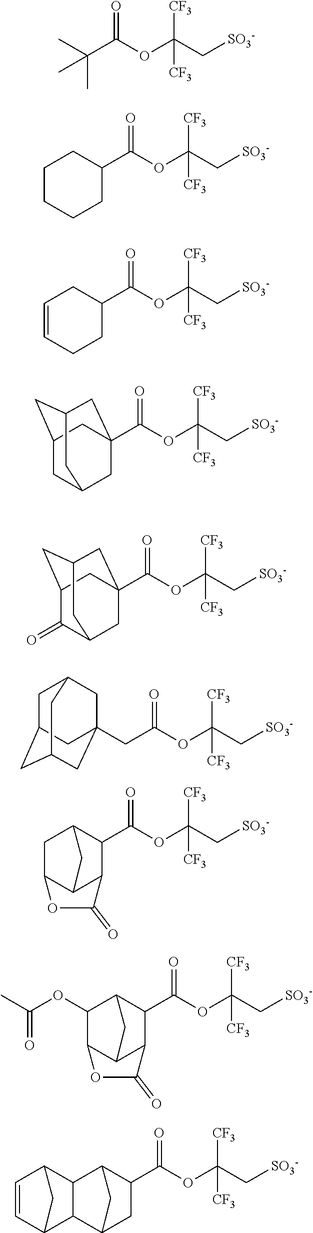

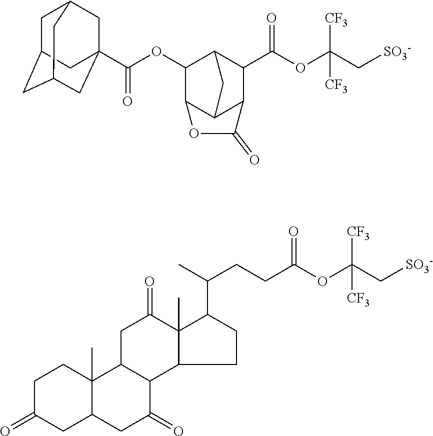

Note that the photo-acid generator containing the anion shown by the general formula (2D) does not have a fluorine atom at a position of the sulfo group, but has two trifluoromethyl groups at B position, thereby providing sufficient acidity to cut the acid-labile group in the base polymer. Thus, this photo-acid generator is utilizable.

As the photo-acid generator, one represented by the following general formula (3) is also favorable.

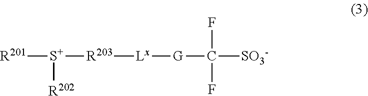

In the general formula (3), R²⁰¹ and R²⁰² each independently represent a hydrocarbyl group having 1 to 20 carbon atoms and optionally containing a heteroatom. R²⁰³ represents a hydrocarbylene group having 1 to 20 carbon atoms and optionally containing a heteroatom. In addition, any two of R²⁰¹, R²⁰², and R²⁰³ may be bonded to each other to form a ring together with a sulfur atom bonded thereto. In this event, examples of the ring include those given as examples of the ring that may be formed by R¹⁰¹ and R¹⁰² being bonded to each other together with the sulfur atom bonded thereto in the description of the general formula (2).

The hydrocarbyl groups represented by R²⁰¹ and R²⁰² may be saturated or unsaturated, and may be linear, branched, or cyclic. Specific examples thereof include: alkyl groups having 1 to 20 carbon atoms, such as a methyl group, an ethyl group, a propyl group, an isopropyl group, an n-butyl group, a sec-butyl group, a tert-butyl group, an n-pentyl group, a tert-pentyl group, an n-hexyl group, an n-octyl group, and a 2-ethylhexyl group; cyclic saturated hydrocarbyl groups having 3 to 20 carbon atoms, such as a cyclopentyl group, a cyclohexyl group, a cyclopentylmethyl group, a cyclopentylethyl group, a cyclohexylmethyl group, a cyclohexylethyl group, a norbornyl group, an oxanorbornyl group, a tricyclo[5.2.1.0^{2,6}]decanyl group, and an adamantyl group; aryl groups having 6 to 20 carbon atoms, such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, and a tert-butylnaphthyl group; and groups which are combinations of the groups. Furthermore, part or all of the hydrogen atoms of these groups may be substituted with a group containing a heteroatom, such as an oxygen atom, a sulfur atom, a nitrogen atom, or a halogen atom, and part of the —CH₂— of these groups may be substituted with a group containing a heteroatom such as an oxygen atom, a sulfur atom, or a nitrogen atom. The resulting hydrocarbyl groups may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride, a haloalkyl group, etc. Among these, R²⁰¹ and R²⁰² are preferably each an aryl group in which a hydrogen atom is optionally substituted.

The hydrocarbylene group represented by R²⁰³ may be saturated or unsaturated, and may be linear, branched, or cyclic. Specific examples thereof include alkanediyl groups having 1 to 20 carbon atoms, such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; cyclic saturated hydrocarbylene groups having 3 to 20 carbon atoms, such as a cyclopentanediyl group, a cyclohexanediyl group, a norbornanediyl group, and an adamantanediyl group; arylene groups having 6 to 20 carbon atoms, such as a phenylene group, a methylphenylene group, an ethylphenylene group, an n-propylphenylene group, an isopropylphenylene group, an n-butylphenylene group, an isobutylphenylene group, a sec-butylphenylene group, a tert-butylphenylene group, a naphthylene group, a methylnaphthylene group, an ethylnaphthylene group, an n-propylnaphthylene group, an isopropylnaphthylene group, an n-butylnaphthylene group, an isobutylnaphthylene group, a sec-butylnaphthylene group, and a tert-butylnaphthylene group; and groups which are combinations of the groups. Furthermore, part or all of the hydrogen atoms of these groups may be substituted with a group containing a heteroatom, such as an oxygen atom, a sulfur atom, a nitrogen atom, or a halogen atom, and part of the —CH₂— of these groups may be substituted with a group containing a heteroatom such as an oxygen atom, a sulfur atom, or a nitrogen atom. The resulting hydrocarbylene group may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride, a haloalkyl group, etc. Among these, R²⁰³ is preferably an arylene group in which a hydrogen atom is optionally substituted.

In the general formula (3), G represents a single bond or a hydrocarbylene group having 1 to 20 carbon atoms and optionally containing a heteroatom. The hydrocarbylene group represented by G may be saturated or unsaturated, and may be linear, branched, or cyclic. Specific examples thereof include those given as examples of the hydrocarbylene group represented by R²⁰³. Furthermore, part or all of the hydrogen atoms of these groups may be substituted with a group containing a heteroatom, such as an oxygen atom, a sulfur atom, a nitrogen atom, or a halogen atom, and part of the —CH₂— of these groups may be substituted with a group containing a heteroatom such as an oxygen atom, a sulfur atom, or a nitrogen atom. The resulting hydrocarbylene group may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride, a haloalkyl group, etc. Among these, G is preferably a methylene group or a methylene group in which a hydrogen atom is substituted with a fluorine atom or a trifluoromethyl group.

In the general formula (3), L^{x} represents a divalent linking group. Examples of the linking group include an ether bond, an ester bond, a thioether bond, a sulfinic acid ester bond, a sulfonic acid ester bond, a carbonate bond, and a carbamate bond.

Examples of the photo-acid generator represented by the general formula (3) include those given as examples of a photo-acid generator represented by a formula (3) in JP 2018-062503 A.

In the resist composition, the contained amount of the photo-acid generator is not particularly limited, but is preferably 0 to 40 parts by mass, more preferably 0.1 to 40 parts by mass, and further preferably 0.1 to 20 parts by mass based on 80 parts by mass of the base polymer. When the amount is in this range, resolution is favorable. One kind of the photo-acid generator may be used, or two or more kinds thereof may be used in combination.

### [Quencher]

The above-described resist composition contains, as an essential component, a quencher as an acid diffusion controller. Examples of the quencher include amine compounds and onium salt compounds. Examples of the amine compounds include primary, secondary, and tertiary amine compounds disclosed in paragraphs [0146] to [0164] of JP 2008-111103 A; in particular, amine compounds having a hydroxy group, an ether bond, an ester bond, a lactone ring, a cyano group, or a sulfonic acid ester bond. Furthermore, examples also include compounds in which a primary or secondary amine is protected with a carbamate group, like the compounds disclosed in JP 3790649 B2. Examples of the onium salt compounds include compounds disclosed in Patent Document 1, JP 2003-005376 A, etc. given above.

It is also possible to use, as a quencher, a sulfonic acid sulfonium salt having a nitrogen-containing substituent. Such a compound functions as a so-called photo-degradable base, which functions as a quencher in unexposed portions and loses the quencher function in exposed portions due to neutralization with the acid generated by itself. Using a photo-degradable base, the contrast between exposed and unexposed portions can be further enhanced. Regarding the photo-degradable base, JP 2009-109595 A, JP 2012-046501 A, etc. may be consulted, for example.

The contained amount of the quencher contained in the resist composition is not particularly limited, but is preferably 0.001 to 12 parts by mass, more preferably 0.01 to 8 parts by mass based on 80 parts by mass of the base polymer. One kind of the quencher may be used, or two or more kinds thereof may be used in combination.

In addition, the photo-acid generator and the quencher contained in the resist composition are not particularly limited. Examples include those disclosed in JP 2010-215608 A.

### [Organic Solvent]

The organic solvent is not particularly limited as long as it is capable of sufficiently dissolving the components contained in the resist composition, and has favorable coating property. Examples of such organic solvents include: cellosolve-based solvents, such as methyl cellosolve acetate; propylene glycol alkyl ether-based solvents, such as propylene glycol monomethyl ether; propylene glycol alkyl ether acetate-based solvents, such as propylene glycol monomethyl ether acetate; ester-based solvents, such as butyl acetate and ethyl lactate; alcohol-based solvents, such as isopropanol; ketone-based solvents, such as cyclohexanone and methyl isobutyl ketone; ether-based solvents, such as methyl phenyl ether; high polarity solvents, such as N-methylpyrrolidone; and mixed solvents thereof.

### [Surfactant]

Here, the above-described resist composition may be used, as necessary, with an added water-repellent composition (surfactant) that exhibits a top coat function in order to reduce the step of applying and forming a top coat at the time of ArF immersion exposure. A water-repellent layer having the top coat function is formed on a resist upper layer film with a uniform film thickness at the time of application. After exposure and a post-exposure bake, the water-repellent layer remains on the resist upper layer film uniformly. However, since there is no change in the composition itself of the water-repellent layer between before the exposure and after the post-exposure bake, the layer is easily removed in the separation step of the dry development when exposed portions and unexposed portions are separated.

Incidentally, the surfactant is preferably insoluble or hardly soluble in water and alkaline developers, or insoluble or hardly soluble in water and soluble in alkaline developers. As such a surfactant, those disclosed in JP 2007-297590 A, JP 2010-215608 A, and JP 2011-016746 A can be referred to.

Examples of the surfactant that is insoluble or hardly soluble in water and alkaline developers include nonionic surfactants including: polyoxyethylene alkyl ethers, such as polyoxyethylene olein ether; polyoxyethylene alkylaryl ethers, such as polyoxyethylene nonylphenol ether; polyoxyethylene polyoxypropylene block copolymers; sorbitane aliphatic acid esters, such as sorbitane monostearate; and polyoxyethylene sorbitane aliphatic acid esters such as polyoxyethylene sorbitane monolaurate. Among the surfactants disclosed in the above-mentioned publications, preferable are FC-4430 (manufactured by 3M Company), Surflon (registered trademark)S-381 (manufactured by AGC Seimi Chemical Co., Ltd.), OLFINE (registered trademark) E1004 (manufactured by Nissin Chemical Industry Co., Ltd.), KH-20 and KH-30 (manufactured by AGC Seimi Chemical Co., Ltd.), an oxetane ring-opened polymer represented by the following general formula (surf-1), etc.

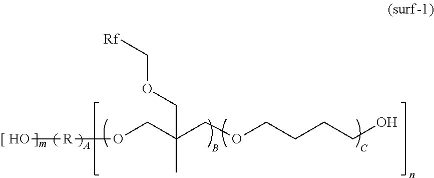

Here, R, Rf, A, B, C, “m”, and “n” apply only to the general formula (surf-1), regardless of the definitions given above. R represents an aliphatic group having a valency of 2 to 4 and having 2 to 5 carbon atoms. As the aliphatic group, examples of divalent groups include an ethylene group, a 1,4-butylene group, a 1,2-propylene group, a 2,2-dimethyl-1,3-propylene group, and a 1,5-pentylene group, and examples of trivalent or tetravalent groups include the following. In the formulae, a broken line represents an attachment point, and each formula respectively represents a partial structure derived from glycerol, trimethylolethane, trimethylolpropane, and pentaerythritol.

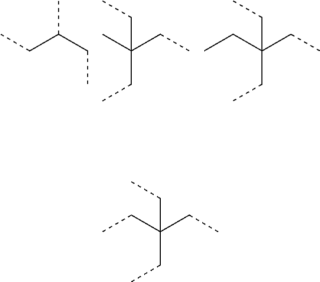

Among these, a 1,4-butylene group, a 2,2-dimethyl-1,3-propylene group, etc. are preferable.

Rf represents a trifluoromethyl group or a pentafluoroethyl group, preferably a trifluoromethyl group. “m” represents an integer of 0 to 3, “n” represents an integer of 1 to 4, and the sum of “n” and “m” represents the valence of R and is an integer of 2 to 4. A represents 1. B represents an integer of 2 to 25, preferably an integer of 4 to 20. C represents an integer of 0 to 10, preferably 0 or 1. Furthermore, each constitutional unit in the general formula (surf-1) does not define the arrangement, and the units may be bonded in blocks or at random. The production of the partially fluorinated oxetane ring-opened polymer-based surfactant is described in detail in U.S. Pat. No. 5,650,483 A etc.

A surfactant insoluble or hardly soluble in water and soluble in alkaline developers has a function of reducing penetration and leaching of water by being oriented on the resist upper layer film surface when a resist top coat is not used in ArF immersion exposure. Therefore, such a surfactant is useful for reducing damage to the exposure apparatus by suppressing elution of water-soluble components from the resist upper layer film, and is also useful since the surfactant is solubilized during development with an alkaline developer after exposure or after a post-exposure bake (PEB) and hardly becomes a foreign substance that causes defects. Such a surfactant has a property that it is insoluble or hardly soluble in water and soluble in alkaline developers, and preferable is a polymer surfactant, in particular, one also called a hydrophobic resin and having a high water-repellency and capable of improving water-sliding property.

Examples of such a polymer surfactant include those including at least one kind selected from repeating units represented by any of the following general formulae (4A) to (4E).

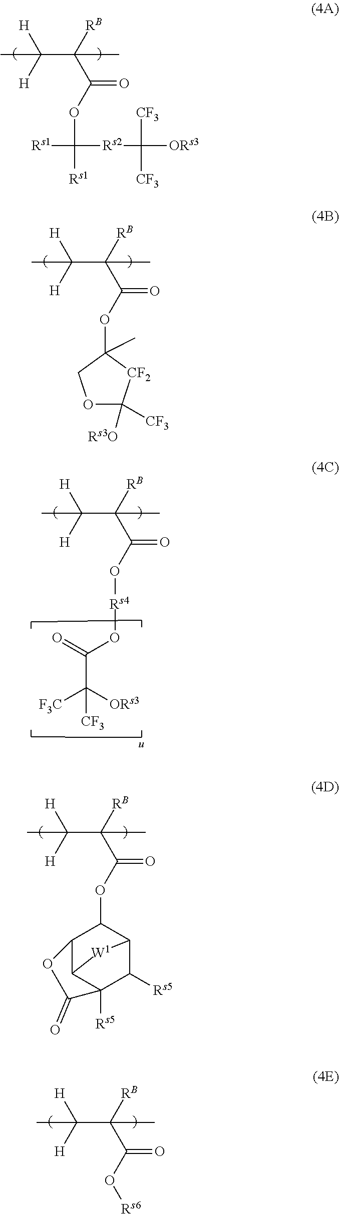

In the general formula (4A) to (4E), R^{B} represents a hydrogen atom, a fluorine atom, a methyl group, or a trifluoromethyl group. W¹ represents —CH₂—, —CH₂CH₂—, —O—, or two —H groups that are separate from each other. Each R^{s1} independently represents a hydrogen atom or a hydrocarbyl group having 1 to 10 carbon atoms. R^{s2} represents a single bond or a linear or branched hydrocarbylene group having 1 to 5 carbon atoms. Each R^{s3} independently represents a hydrogen atom, a hydrocarbyl group or fluorinated hydrocarbyl group having 1 to 15 carbon atoms, or an acid-labile group. When R^{s3} is a hydrocarbyl group or a fluorinated hydrocarbyl group, the group may have an intervening ether bond or carbonyl group in a carbon-carbon bond. R^{s4} represents a (u+1)-valent hydrocarbon group or fluorinated hydrocarbon group having 1 to 20 carbon atoms. “u” represents an integer of 1 to 3. Each R^{s5} independently represents a hydrogen atom or a group represented by —C(═O)—O—R^{s7}. R^{s7} represents a fluorinated hydrocarbyl group having 1 to 20 carbon atoms. R^{s6} represents a hydrocarbyl group or fluorinated hydrocarbyl group having 1 to 15 carbon atoms, and optionally has an intervening ether bond or carbonyl group in a carbon-carbon bond thereof.

The hydrocarbyl group represented by R^{s1} may be linear, branched, or cyclic, and specific examples thereof include a methyl group, an ethyl group, an n-propyl group, an isopropyl group, a cyclopropyl group, an n-butyl group, an isobutyl group, a sec-butyl group, a tert-butyl group, a cyclobutyl group, an n-pentyl group, a cyclopentyl group, an n-hexyl group, a cyclohexyl group, an n-heptyl group, an n-octyl group, an n-nonyl group, an n-decyl group, an adamantyl group, and a norbornyl group. Among these, groups having 1 to 6 carbon atoms are preferable.

The hydrocarbylene group represented by R^{s2} may be linear, branched, or cyclic, and specific examples thereof include a methylene group, an ethylene group, a propylene group, a butylene group, and a pentylene group.

The hydrocarbyl groups represented by R^{s3} and R^{s6} may be linear, branched, or cyclic, and specific examples thereof include alkyl groups, alkenyl groups, and alkynyl groups, and alkyl groups are preferable. Examples of the alkyl groups include, besides those given as examples of the hydrocarbyl group represented by R^{s1}, an n-undecyl group, an n-dodecyl group, a tridecyl group, a tetradecyl group, and a pentadecyl group. Examples of the fluorinated hydrocarbyl groups represented by R^{s3} and R^{s6} include groups which are the above-described hydrocarbyl groups in which part or all of the hydrogen atoms bonded to the carbon atoms of the hydrocarbyl groups are substituted with fluorine atoms. As described above, the fluorinated hydrocarbyl groups may have an intervening ether bond or carbonyl group in a carbon-carbon bond thereof.

Examples of the acid-labile group represented by R^{s3} include groups represented by the general formulae (L1) to (L4), tertiary hydrocarbyl groups having 4 to 20, preferably 4 to 15, carbon atoms, trialkylsilyl groups in which each alkyl group has 1 to 6 carbon atoms, and oxoalkyl groups having 4 to 20 carbon atoms.

The (u+1)-valent hydrocarbon group or fluorinated hydrocarbon group represented by R^{s4} may be linear, branched, or cyclic, and specific examples thereof include groups obtained by further “u” hydrogen atoms being removed from the above-described hydrocarbyl groups, fluorinated hydrocarbyl groups, etc.

The fluorinated hydrocarbyl group represented by R^{s7} may be linear, branched, or cyclic, and specific examples thereof include groups in which part or all of the hydrogen atoms of the above hydrocarbyl group are substituted with fluorine atoms. Specific examples thereof include a trifluoromethyl group, a 2,2,2-trifluoroethyl group, a 3,3,3-trifluoro-1-propyl group, a 3,3,3-trifluoro-2-propyl group, a 2,2,3,3-tetrafluoropropyl group, a 1,1,1,3,3,3-hexafluoroisopropyl group, a 2,2,3,3,4,4,4-heptafluorobutyl group, a 2,2,3,3,4,4,5,5-octafluoropentyl group, a 2,2,3,3,4,4,5,5,6,6,7,7-dodecafluoroheptyl group, a 2-(perfluorobutyl)ethyl group, a 2-(perfluorohexyl)ethyl group, a 2-(perfluorooctyl)ethyl group, and a 2-(perfluorodecyl)ethyl group.

Examples of the repeating units represented by any of the general formulae (4A) to (4E) include the following, but are not limited thereto. Note that, in the following formulae, R^{B} is as defined above.

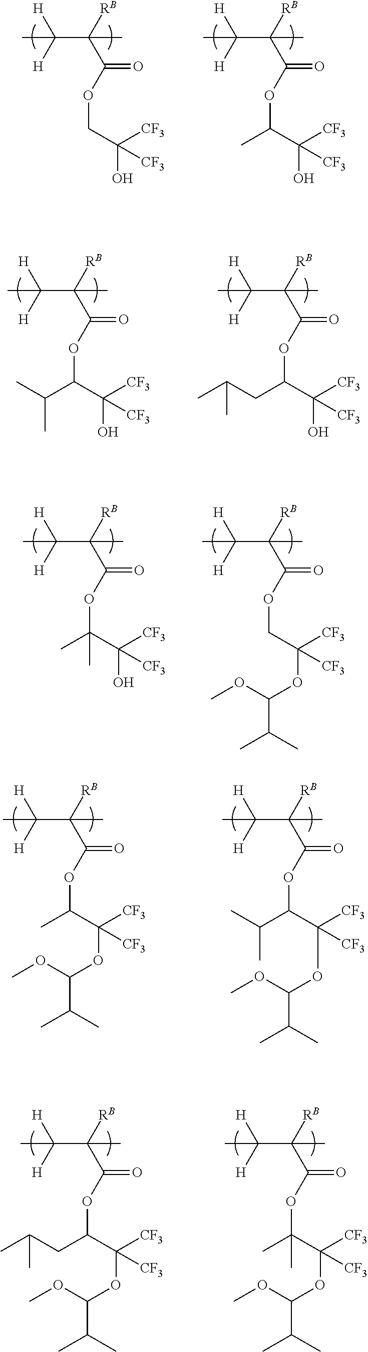

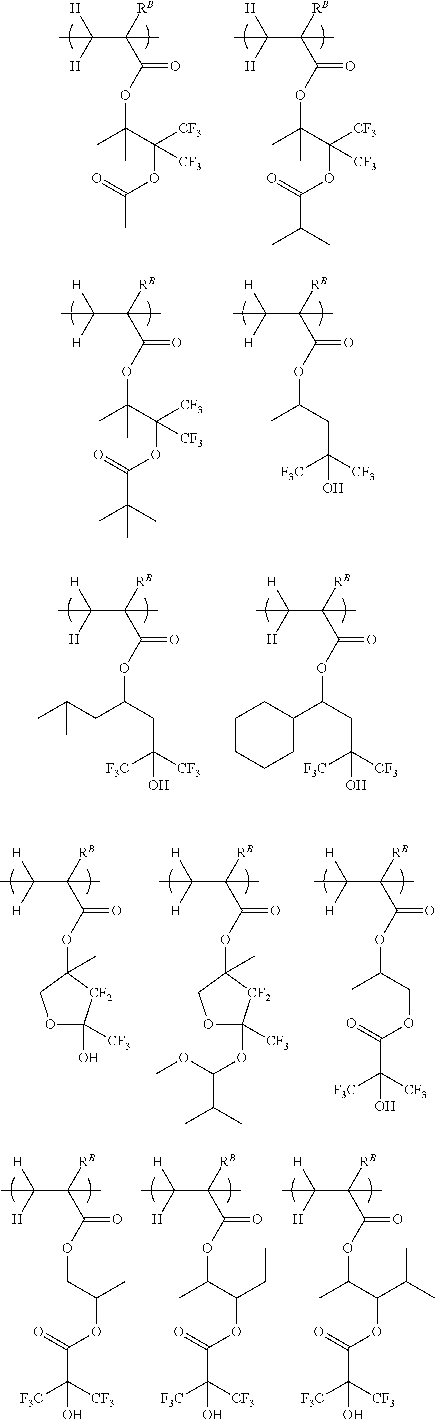

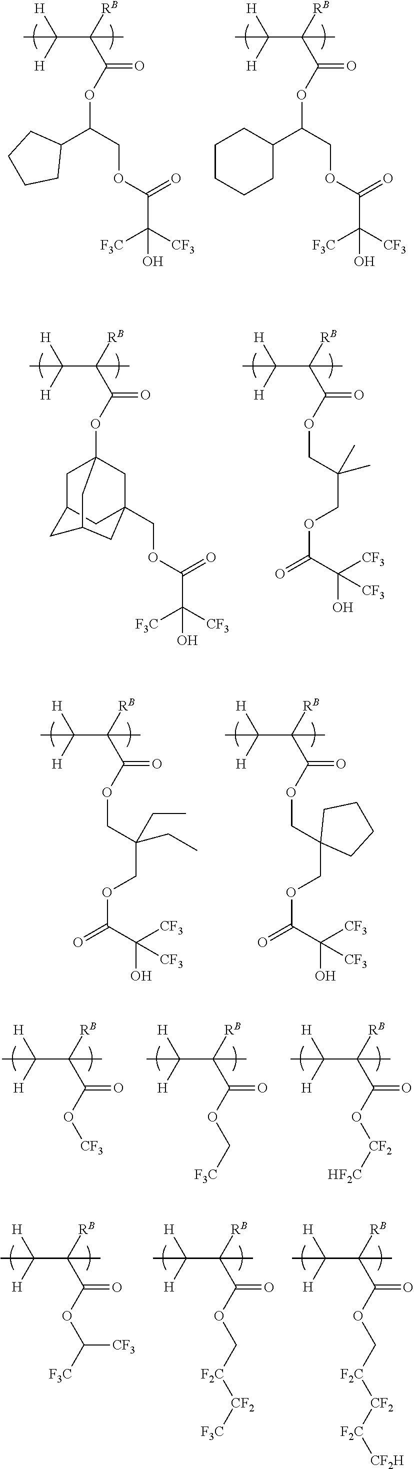

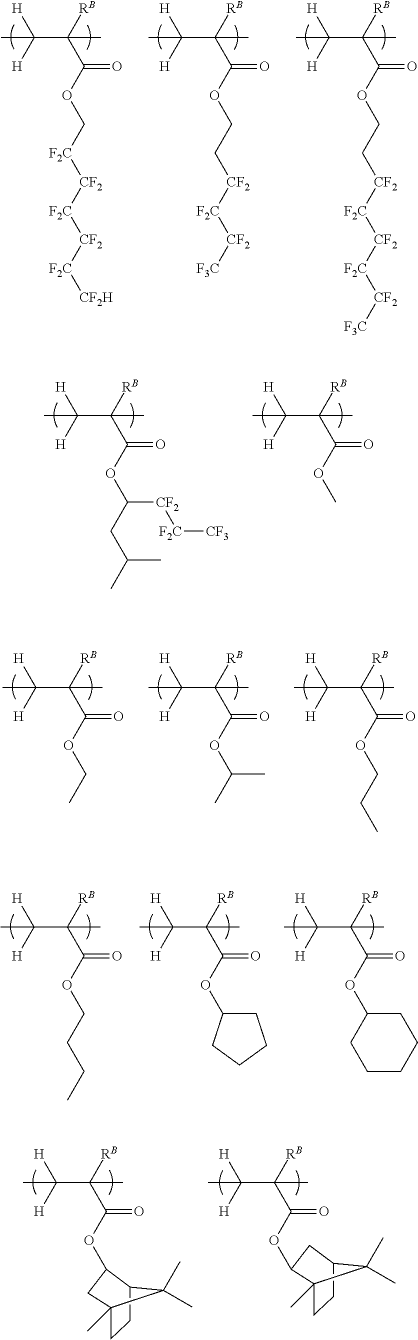

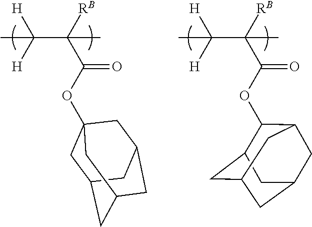

The polymer surfactant may further have a repeating unit other than the repeating unit represented by the general formulae (4A) to (4E). Examples of the other repeating unit include repeating units obtained from methacrylic acid, an α-trifluoromethylacrylic acid derivative, etc. In the polymer surfactant, the contained amount of the repeating units represented by the general formulae (4A) to (4E) is preferably 20 mol % or more, more preferably 60 mol % or more, and further preferably 100 mol % of all the repeating units.

The molecular weight Mw of the polymer surfactant is preferably 1,000 to 50,000, more preferably 2,000 to 20,000. Within this range, the surface modification effect is sufficient, and development defects rarely occur.

Examples of a method for synthesizing the polymer surfactant include a method in which, in an organic solvent, monomers having an unsaturated bond to yield the repeating unit represented by the general formulae (4A) to (4E) and, as necessary, other repeating units are added with a radical initiator and heated to be polymerized. Examples of the organic solvent used in the polymerization include toluene, benzene, THF, diethyl ether, and dioxane. Examples of the polymerization initiator include AIBN, 2,2′-azobis(2,4-dimethylvaleronitrile), dimethyl 2,2′-azobis(2-methylpropionate), benzoyl peroxide, and lauroyl peroxide. The reaction temperature is preferably 50 to 100° C. The reaction time is preferably 4 to 24 hours. The acid-labile group may be introduced into the monomer to be used as it is, or may be protected or partially protected after the polymerization.

When the polymer surfactant is synthesized, known chain transfer agents, such as dodecyl mercaptan and 2-mercaptoethanol, may be used to regulate the molecular weight. In this case, the addition amount of these chain transfer agents is preferably 0.01 to 10 mol % relative to the total number of moles of the monomers to be polymerized.

Regarding the surfactant that is insoluble or hardly soluble in water and soluble in alkaline developers, it is also possible to consult JP 2008-122932 A, JP 2010-134012 A, JP 2010-107695 A, JP 2009-276363 A, JP 2009-192784 A, JP 2009-191151 A, JP 2009-098638 A, JP 2010-250105 A, JP 2011-042789 A, etc.

The contained amount of the surfactant is preferably 0 to 20 parts by mass based on 80 parts by mass of the base polymer. When the surfactant is contained, the lower limit of the amount is preferably 0.001 parts by mass, more preferably 0.01 parts by mass. Meanwhile, the upper limit of the amount is preferably 15 parts by mass, more preferably 10 parts by mass. One kind of the surfactant may be used, or two or more kinds thereof may be used in combination.

### [Patterning Process]

As a patterning means, the above-described resist composition is applied to form a film on a substrate to be processed, such as a multilayer containing the Si element, ArF immersion exposure and a post-exposure bake are performed, dry development is subsequently performed using a gas plasma containing oxygen gas, and a resist pattern is separated. Subsequently, the resist pattern is transferred to the substrate to be processed under dry etching conditions including fluorine gas.

That is, the present invention provides a patterning process including the steps of:
forming a multilayer on a substrate to be processed;
forming a resist upper layer film by using a positive chemically-amplified resist composition for ArF excimer containing, at least, a base polymer having a (meth)acrylic structure substituted with an acid-labile group, a photo-acid generator, a quencher having a function of controlling acid diffusion, and an organic solvent;
removing the acid-labile group in an exposed portion of the resist upper layer film by exposure and a post-exposure bake;
performing a hard bake at a higher temperature and for a shorter time than the post-exposure bake to allow the removed acid-labile group to volatilize out of the resist upper layer film and cause a difference in a number of carbon atoms between an unexposed portion and the exposed portion;
removing the resist upper layer film in the exposed portion with a gas plasma containing oxygen by dry development to separate a pattern; and
transferring the pattern of the resist upper layer film to the multilayer underneath by etching.

The substrate to be processed used in the inventive patterning process is not particularly limited, and, for example, a wafer substrate having a film to be processed formed thereon can be used. Examples of the film to be processed include a silicon oxide film.

The multilayer formed on the substrate to be processed is not particularly limited as long as it includes two or more layers. A multilayer underlayer formed on the substrate to be processed can be, for example, a coating-type carbon film. A multilayer middle layer formed on the multilayer underlayer can be, for example, a coating-type Si-containing antireflective film.

Examples of the resist composition for forming the resist upper layer film include the above-described resist composition. Meanwhile, the method for forming the resist upper layer film is not particularly limited, and a known method can be employed.

The conditions when exposing the resist upper layer film are not particularly limited, and, for example, when a fine line-and-space pattern is to be formed, a predetermined pattern can be formed by using dipole illumination conditions.

To achieve a predetermined deprotection reaction of acid-labile groups having a high protection rate of 80% to 100% and to achieve a predetermined volatilization action of the removed acid-labile groups, baking is performed as a first low-temperature bake (PEB) and a second high-temperature bake (hard bake; the second high-temperature bake determines the result of the pattern after dry development). Incidentally, the first low-temperature bake, that is, the post-exposure bake, is preferably carried out in 40 seconds to 120 seconds, more preferably 60 seconds to 120 seconds, and the second high-temperature bake, that is, the hard bake, is preferably carried out within 40 seconds.

The first low-temperature bake is preferably 80° C. to 120° C. Meanwhile, the second high-temperature bake is carried out at a higher temperature than the first low-temperature bake. Incidentally, the second high-temperature bake is preferably 130° C. or higher, more preferably 150° C. or higher.

That is, it is preferable to perform the post-exposure bake at 80° C. to 120° C. for 40 seconds to 120 seconds, and perform the hard bake at 130° C. or higher for less than 40 seconds. Furthermore, the hard bake is more preferably performed at 150° C. or higher for less than 40 seconds.

Either an acid-labile group that undergoes a deprotection reaction in a low-temperature PEB or an acid-labile group that undergoes a deprotection reaction in a high-temperature PEB can be used as long as the acid-labile group is volatilized out of the resist upper layer film by the hard bake. In particular, the acid-labile group preferably has 4 to 9 carbon atoms. Incidentally, as the acid-labile group having 4 to 9 carbon atoms, an acid-labile group having a cyclic skeleton is preferable.

Furthermore, the base polymer having a (meth)acrylic structure substituted with an acid-labile group that is removed in a PEB and volatilized in a hard bake is not limited to a single kind, and it is possible to use a base polymer substituted with multiple kinds of acid-labile groups.

Furthermore, it is preferable that the resist composition further contains a surfactant that functions as a top coat for ArF immersion exposure, or the patterning process further includes a step of applying and forming a top coat before the exposure.

The dry development is not particularly limited as long as a gas plasma containing oxygen is used.

The method for transferring the pattern of the resist upper layer film to the multilayer underneath by etching is not particularly limited, and a known method can be employed.

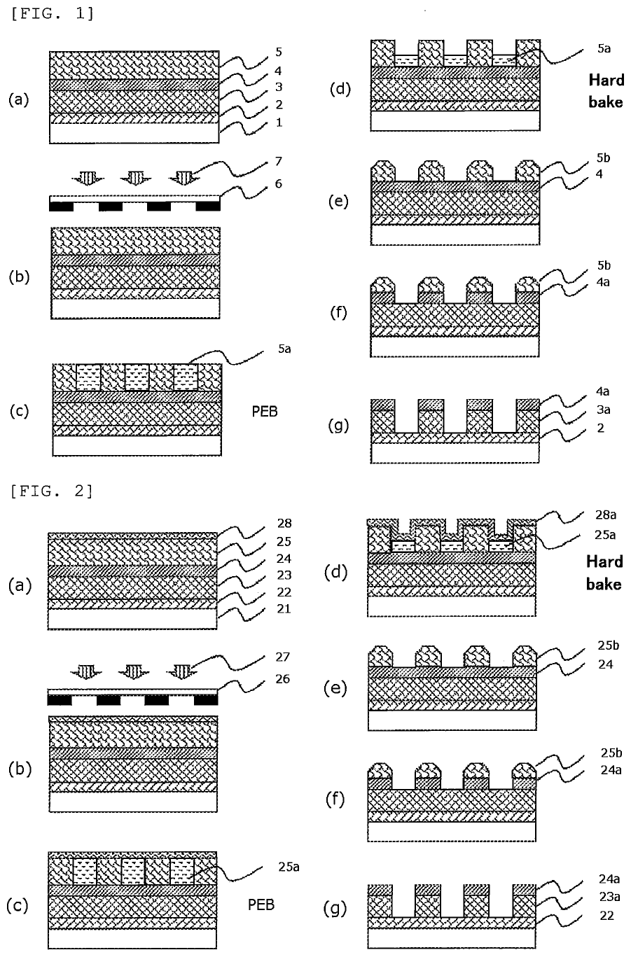

An example of the inventive patterning process will be described with reference to FIG. 1. On a substrate to be processed in which a film 2 to be processed has been formed on a wafer substrate 1, a multilayer including a coating-type carbon film 3 and a coating-type Si-containing antireflective film 4 is formed, and an ArF positive chemically amplified resist upper layer film 5 is formed thereon by using an ArF positive chemically-amplified resist composition (FIG. 1(a)). Subsequently, the ArF positive chemically amplified resist upper layer film is exposed using a reticle 6 and ArF exposure light 7 (FIG. 1(b)). Subsequently, a PEB is performed to form exposed resist portions 5a, where acid-labile groups have been deprotected, in the ArF positive chemically amplified resist upper layer film (FIG. 1(c)). Subsequently, a hard bake is performed to allow the acid-labile groups to volatilize from the exposed resist portions 5a, in which the acid-labile groups have been deprotected (FIG. 1(d)). Subsequently, the exposed resist portions are removed by dry development by using a gas plasma containing oxygen to form a resist pattern 5b (FIG. 1(e)). Subsequently, the pattern is transferred to the coating-type Si-containing antireflective film while using the resist pattern 5b as a mask to form a coating-type Si-containing antireflective film pattern 4a (FIG. 1(f)). Subsequently, the pattern is transferred to the coating-type carbon film while using the coating-type Si-containing antireflective film pattern 4a as a mask to form a coating-type carbon film pattern 3a (FIG. 1(g)).

A different example of the inventive patterning process will be described with reference to FIG. 2. On a substrate to be processed in which a film 22 to be processed has been formed on a wafer substrate 21, a multilayer including a coating-type carbon film 23 and a coating-type Si-containing antireflective film 24 is formed, an ArF positive chemically amplified resist upper layer film 25 is formed thereon by using an ArF positive chemically-amplified resist composition, and an immersion top coat film 28 is formed thereon (FIG. 2(a)). Subsequently, the ArF positive chemically amplified resist upper layer film is exposed using a reticle 26 and ArF exposure light 27 (FIG. 2(b)). Subsequently, a PEB is performed to form exposed resist portions 25a, where acid-labile groups have been deprotected, in the ArF positive chemically amplified resist upper layer film (FIG. 2(c)). Subsequently, a hard bake is performed to allow the acid-labile groups to volatilize from the exposed resist portions 25a, in which the acid-labile groups have been deprotected, underneath the immersion top coat film 28a (FIG. 2(d)). Subsequently, the exposed resist portions are removed by dry development by using a gas plasma containing oxygen to form a resist pattern 25b (FIG. 2(e)). Subsequently, the pattern is transferred to the coating-type Si-containing antireflective film while using the resist pattern 25b as a mask to form a coating-type Si-containing antireflective film pattern 24a (FIG. 2(f)). Subsequently, the pattern is transferred to the coating-type carbon film while using the coating-type Si-containing antireflective film pattern 24a as a mask to form a coating-type carbon film pattern 23a (FIG. 2(g)).

### EXAMPLES

Hereinafter, the present invention will be described specifically with reference to Examples and Comparative Examples, but the present invention is not limited to the Examples.

### (Preparation of Resist Compositions)

According to a predetermined synthesizing method, a base polymer having a predetermined number of carbon atoms and a predetermined substitution rate was prepared, an acid generator, a quencher, and water repellent (surfactant) for immersion were dissolved in an organic solvent of PGMEA to prepare a solution, and then, the solution was filtered with a 0.2-μm filter made of Teflon (registered trademark). Thus, resist compositions R1 to R16, R21 to R2C, R31, R32, and R41 to R48 (compositions in which the rate of protection with an acid-labile group is 10%, 30%, 80%, and 100% each for acid-labile groups having 4, 5, 8, or 9 carbon atoms, compositions in which the rate of protection with an acid-labile group is 10% and 90% each for acid-labile groups having 4, 5, 8, 9, or 10 carbon atoms, a composition in which the rate of protection with an acid-labile group is 100% for an acid-labile group having 9 carbon atoms, and compositions in which the rate of protection with an acid-labile group is 100%, 90%, 80%, 70%, 60%, 50%, 40%, and 10% each for an acid-labile group having 9 carbon atoms) were prepared. Note that the protection rate is a value determined using NMR. The structures of the repeating units AL1 to AL5 and the structural formulae of the photo-acid generator AG1, the quencher Q1, and the water repellent PF1 are as follows.

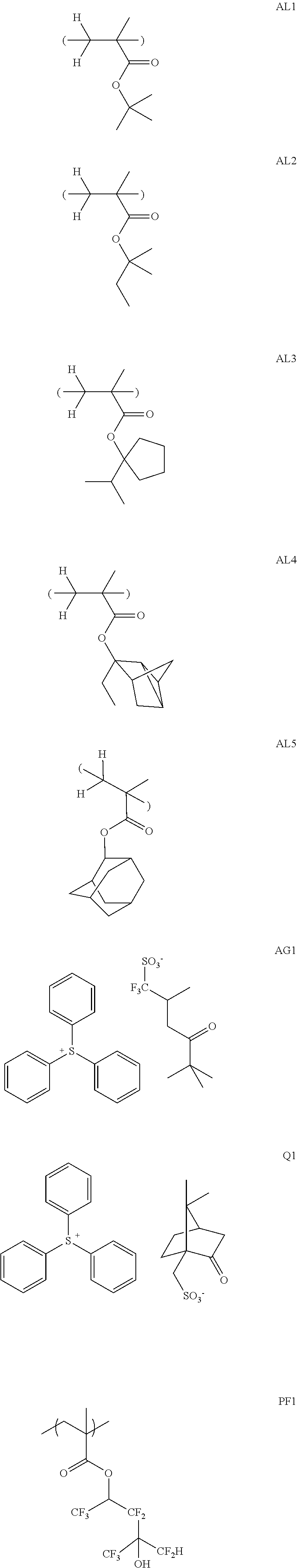

### (Resist Pattern Formation Evaluation 1)

Table 1 is a table of evaluation samples of an Example (resist pattern formation evaluation 1) for finding out the protection rate (substitution rate) dependence of the acid-labile groups.

TABLE 1

| | Base polymer | | Photo- | | | |
|---|---|---|---|---|---|---|
| | 100 parts | | acid | | | |
| | Acid- | Pro- | generator | Quencher | Water | Solvent |
| Sample | labile | tection | 10 parts | 5 parts | repellent | PGMEA |
| name | group | rate % | Type | Type | 5 parts | % |
| R1 | AL1 | 10 | AG1 | Q1 | PF1 | 100 |
| R2 | AL1 | 30 | AG1 | Q1 | PF1 | 100 |
| R3 | AL1 | 80 | AG1 | Q1 | PF1 | 100 |
| R4 | AL1 | 100 | AG1 | Q1 | PF1 | 100 |
| R5 | AL2 | 10 | AG1 | Q1 | PF1 | 100 |
| R6 | AL2 | 30 | AG1 | Q1 | PF1 | 100 |
| R7 | AL2 | 80 | AG1 | Q1 | PF1 | 100 |
| R8 | AL2 | 100 | AG1 | Q1 | PF1 | 100 |
| R9 | AL3 | 10 | AG1 | Q1 | PF1 | 100 |
| R10 | AL3 | 30 | AG1 | Q1 | PF1 | 100 |
| R11 | AL3 | 80 | AG1 | Q1 | PF1 | 100 |
| R12 | AL3 | 100 | AG1 | Q1 | PF1 | 100 |
| R13 | AL4 | 10 | AG1 | Q1 | PF1 | 100 |
| R14 | AL4 | 30 | AG1 | Q1 | PF1 | 100 |
| R15 | AL4 | 80 | AG1 | Q1 | PF1 | 100 |
| R16 | AL4 | 100 | AG1 | Q1 | PF1 | 100 |

Firstly, multilayer films (54 nm of a coating-type carbon film was formed by a treatment at 250° C. in 60 seconds, and 18 nm of a Si-containing antireflective film was formed by a treatment at 220° C. in 60 seconds) were respectively formed on a film (SiO film) to be processed of a wafer, and a coating film of each of the resist compositions shown in Table 1 was respectively formed thereon by spin-coating and prebaking. The prebaking was performed at 120° C. for 60 seconds, and each sample wafer, having a resist film thickness of 130 nm, was obtained.

Subsequently, using an ArF immersion exposure apparatus, a 40 nm half-pitch line-and-space pattern formed in a binary reticle was exposed with a lens numerical aperture of 1.35 NA under a constant exposure condition of 25 mJ/cm². Subsequently, each of the exposed wafers was subjected to a PEB (Post Exposure Bake) treatment on a hot plate at 90° C. for 90 seconds. Subsequently, a hard bake was performed at 150° C. for 30 seconds, and the step between the exposed portions and the unexposed portions of each sample after the hard bake was measured using an AFM (Atomic Force Microscope). The results are summarized in Table 2.

TABLE 2

| | |
|---|---|
| | Film loss amount (nm) in exposed portions |
| Base | after hard bake (initial film thickness 130 nm) |

| polymer | AL1 | AL2 | AL3 | AL4 |
|---|---|---|---|---|
| (sample | 4 carbon | 5 carbon | 8 carbon | 9 carbon |
| name) | atoms | atoms | atoms | atoms |
| Protection | 7.1 (R1) | 9.0 (R5) | 13.4 (R9) | 14.7 (R13) |
| rate 10% | | | | |
| Protection | 19.0 (R2) | 23.6 (R6) | 32.9 (R10) | 35.4 (R14) |
| rate 30% | | | | |
| Protection | 40.2 (R3) | 47.4 (R7) | 60.2 (R11) | 63.3 (R15) |
| rate 80% | | | | |
| Protection | 46.3 (R4) | 53.9 (R8) | 66.8 (R12) | 69.9 (R16) |
| rate 100% | | | | |

Regarding the resist compositions (R1 to R16) of the base polymers protected (substituted) with a group having 4 to 9 carbon atoms, the film loss in exposed portions was observed after the hard bake. The greater the number of carbon atoms was, the greater the film loss amount in exposed portions after the hard bake was.

Subsequently, the evaluation samples of Table 2 were subjected to dry development, and the remaining resist film in unexposed portions after separation of the resist pattern was measured. The results are shown in Table 3. Note that the conditions of the dry development were as follows.
Chamber pressure: 30 mT
RF-power (upper portion): 200 W
RF-power (lower portion): 100 W
O₂ gas flow rate: 20 sccm
N₂ gas flow rate: 290 sccm
Etching time: 6 seconds

TABLE 3

| | |
|---|---|
| | Remaining film thickness (nm) in unexposed |
| | portions after dry development |
| Base | (initial film thickness 130 nm) |

| polymer | 4 carbon | 5 carbon | 8 carbon | 9 carbon |
|---|---|---|---|---|
| (sample | atoms | atoms | atoms | atoms |
| name) | AL1 | AL2 | AL3 | AL4 |
| Protection | 16.5 (R1) | 20.1 (R5) | 31.2 (R9) | 34.7 (R13) |
| rate 10% | | | | |
| Protection | 28.6 (R2) | 34.0 (R6) | 60.6 (R10) | 65.1 (R14) |
| rate 30% | | | | |
| Protection | 64.7 (R3) | 71.6 (R7) | 86.8 (R11) | 90.4 (R15) |
| rate 80% | | | | |
| Protection | 70.9 (R4) | 77.5 (R8) | 91.6 (R12) | 95.0 (R16) |
| rate 100% | | | | |

A remaining resist film in unexposed portions was successfully maintained after dry development in every one of the evaluation samples R1 to R16, where the protection rate was 10% to 100% and the number of carbon atoms was 4 to 9. The greater the number of carbon atoms was and the higher the protection rate was, the greater the remaining film in the unexposed portions was.

### (Resist Pattern Formation Evaluation 2)

Table 4 shows the results on investigating the influence when the base polymer contains a type of protecting group that does not volatilize, regarding the film loss amount in exposed portions after the hard bake and the remaining film thickness after the dry development. As an acid-labile group that volatilizes in the hard bake, a structure having 4 to 9 carbon atoms was used, and as a structure that does not volatilize in the hard bake, a structure having a high-temperature-activation energy type acid-labile group having 10 carbon atoms was used in this case. Note that the protection rate (substitution rate) of the base polymer was 10% to 90%.

TABLE 4

| | Rate (%) of | | | | | Photo- | | | |
|---|---|---|---|---|---|---|---|---|---|
| | protection with | | | | | acid | | Water | |
| | acid-labile group | | | | | generator | Quencher | repellent | Solvent |
| Sample | (type) | | | | | AG1 | Q1 | PF1 | PGMEA |
| name | AL1 | AL2 | AL3 | AL4 | AL5 | Parts | Parts | Parts | % |
| R21 | 90 | — | — | — | 10 | 10 | 8 | 5 | 100 |
| R22 | 10 | — | — | — | 10 | 10 | 8 | 5 | 100 |
| R23 | 10 | | — | — | 90 | 10 | 8 | 5 | 100 |
| R24 | — | 90 | — | — | 10 | 10 | 8 | 5 | 100 |
| R25 | — | 10 | — | — | 10 | 10 | 8 | 5 | 100 |
| R26 | — | 10 | — | — | 90 | 10 | 8 | 5 | 100 |
| R27 | — | — | 90 | — | 10 | 10 | 8 | 5 | 100 |
| R28 | — | — | 10 | — | 10 | 10 | 8 | 5 | 100 |
| R29 | — | — | 10 | — | 90 | 10 | 8 | 5 | 100 |
| R2A | — | — | | 90 | 10 | 10 | 8 | 5 | 100 |
| R2B | — | — | | 10 | 10 | 10 | 8 | 5 | 100 |
| R2C | — | — | | 10 | 90 | 10 | 8 | 5 | 100 |

Firstly, multilayer films (54 nm of a coating-type carbon film was formed by a treatment at 250° C. in 60 seconds, and 18 nm of a Si-containing antireflective film was formed by a treatment at 220° C. in 60 seconds) were respectively formed on a film (SiO film) to be processed of a wafer, and a coating film of each of the resist compositions shown in Table 4 was respectively formed thereon by spin-coating and prebaking. The prebaking was performed at 120° C. for 60 seconds, and each sample wafer, having a resist film thickness of 130 nm, was obtained.

Subsequently, using an ArF immersion exposure apparatus, a 40 nm half-pitch line-and-space pattern formed in a binary reticle was exposed with a lens numerical aperture of 1.35 NA under a constant exposure condition of 25 mJ/cm². Subsequently, each of the exposed wafers was subjected to a PEB (Post Exposure Bake) treatment on a hot plate at 90° C. for 90 seconds. Then, a treatment was performed at 150° C. for 30 seconds as a hard bake.

The upper row of Table 5 shows the result of measuring, using an AFM (Atomic Force Microscope), the step between the exposed portions and the unexposed portions of each sample after the hard bake, and the lower row of the table shows the result of measuring remaining film thickness of the unexposed portions after the subsequent dry development under conditions of gas plasma containing oxygen gas. Note that the conditions of the dry development were as follows.
Chamber pressure: 30 mT
RF-power (upper portion): 200 W
RF-power (lower portion): 100 W
O₂ gas flow rate: 20 sccm
N₂ gas flow rate: 290 sccm
Etching time: 6 seconds

TABLE 5

| | Acid-labile group | | | | | | | |
|---|---|---|---|---|---|---|---|---|
| Acid- | 4 carbon | | 5 carbon | | 8 carbon | | 9 carbon | |
| labile | atoms | | atoms | | atoms | | atoms | |
| group | AL1 | | AL2 | | AL3 | | AL4 | |
| 10 | R21 | 39.4 | R24 | 46.6 | R27 | 59.3 | R2A | 62.5 |
| carbon | | 66.1 | | 72.1 | | 86.2 | | 89.7 |
| atoms | R22 | 6.2 | R25 | 7.9 | R28 | 11.8 | R2B | 12.9 |
| AL5 | | 28.4 | | 30.7 | | 38.0 | | 40.5 |
| | R23 | 3.1 | R26 | 3.9 | R29 | 6.0 | R2C | 6.6 |
| | | 11.8 | | 12.7 | | 15.7 | | 16.9 |

Film loss in exposed portions after the hard bake and a remaining resist film in unexposed portions after the dry development were observed in every one of the evaluation samples R21 to R2C, where the acid-labile groups had 4 to 9 carbon atoms. Pattern separation achieved by the step and the dry development were successfully achieved in the resist evaluation samples having 4 to 9 carbon atoms even when the base polymer contained an acid-labile group having 10 carbon atoms that does not volatilize after the hard bake. However, compared to the resist compositions of the base polymers protected with a single kind of acid-labile group, the remaining film thickness after the dry development was thin. In addition, the higher the rate of protection with the acid-labile group that volatilizes in the hard bake was, the greater the film loss of the exposed portions was, and the thicker the remaining film in the unexposed portions was after the dry development.

### (Resist Pattern Formation Evaluation 3)

Table 6 shows Examples (resist pattern formation evaluation 3) where a resist composition containing a water repellent for ArF immersion was used, and where a coating-type top coat film was used instead of the water repellent.

TABLE 6

| | | Resist composition | | | | |
|---|---|---|---|---|---|---|
| | | Rate of | | | | |
| | | protection | Photo-acid | | Water | |
| | | with acid- | generator | Quencher | repellent | Solvent |
| | | labile group | AG1 | Q1 | PF1 | PGMEA |
| Sample name | | 100% | Parts | Parts | Parts | % |
| Resist | R31 | AL4 | 10 | 5 | 5 | 100 |
| pattern | R32 | AL4 | 10 | 5 | 0 | 100 |
| formation | | | | | | |
| evaluation 3 | | | | | | |

Multilayer films (54 nm of a coating-type carbon film was formed by a treatment at 250° C. in 60 seconds, and 18 nm of a Si-containing antireflective film was formed by a treatment at 220° C. in 60 seconds) were respectively formed on a film (SiO film) to be processed of a wafer, and a coating film of each of the resist compositions of Table 6 was respectively formed thereon by spin-coating and prebaking. The prebaking was performed at 120° C. for 60 seconds, and each sample wafer, having a resist film thickness of 130 nm, was obtained.

Subsequently, the evaluation resist sample wafer having no added water repellent was spin-coated with a top coat agent constituted by an alcohol solvent, and baking was performed at 100° C. for 60 seconds to form a 30-nm thick top coat film.

Subsequently, using an ArF immersion exposure apparatus, a 40 nm half-pitch line-and-space pattern formed in a binary reticle was exposed with a lens numerical aperture of 1.35 NA under a constant exposure condition of 25 mJ/cm². Subsequently, each of the exposed wafers was subjected to a PEB (Post Exposure Bake) treatment on a hot plate at 90° C. for 90 seconds. Then, a treatment was performed at 150° C. for 30 seconds as a hard bake.

The step between the exposed portions and the unexposed portions of each sample after the hard bake was measured using an AFM (Atomic Force Microscope). After that, the remaining resist film in the unexposed portions after the dry development under conditions of gas plasma containing oxygen gas was measured. The results are shown in Table 7. Note that the conditions of the dry development were as follows.
Chamber pressure: 30 mT
RF-power (upper portion): 200 W
RF-power (lower portion): 100 W
O₂ gas flow rate: 20 sccm
N₂ gas flow rate: 290 sccm
Etching time: 6 seconds

TABLE 7

| | Film loss amount (nm) | Remaining resist film |
|---|---|---|
| | in exposed portions | thickness (nm) after dry |
| | after hard bake | development |
| R31 | 70.0 | 95.0 |
| R32 | 70.0 | 95.0 |

Even when a top coat film was formed on the film formed from the resist composition, film loss in the exposed portions after the hard bake and pattern separation achieved by the dry development were observed.

### (Resist Pattern Formation Evaluation 4)

Table 8 shows Examples for investigating pattern edge roughness in dry development and pattern edge roughness in ordinary alkaline wet development (Comparative Example).

TABLE 8

| | Resist composition | | | | | |
|---|---|---|---|---|---|---|
| | | | | Photo- | | |
| | | Acid- | Protection | acid | | Solvent |
| Sample | Sample | labile | rate | generator | Quencher | PGMEA |
| wafer | name | group | % | 10 parts | 5 parts | % |
| SL1 | R41 | AL4 | 100 | AG1 | Q1 | 100 |
| SL2 | R42 | AL4 | 90 | AG1 | Q1 | 100 |
| SL3 | R43 | AL4 | 80 | AG1 | Q1 | 100 |
| SL4 | R44 | AL4 | 70 | AG1 | Q1 | 100 |
| SL5 | R45 | AL4 | 60 | AG1 | Q1 | 100 |
| SL6 | R46 | AL4 | 50 | AG1 | Q1 | 100 |
| SL7 | R47 | AL4 | 40 | AG1 | Q1 | 100 |
| SL8 | R48 | AL4 | 10 | AG1 | Q1 | 100 |

| | |
|---|---|
| RF1 | Immersion topcoat-less positive chemically |
| | amplified resist composition produced in-house |

Multilayer films (54 nm of a coating-type carbon film was formed by a treatment at 250° C. in 60 seconds, and 18 nm of a Si-containing antireflective film was formed by a treatment at 220° C. in 60 seconds) were respectively formed on a film (SiO film) to be processed of a wafer, and a coating film of each of the resist compositions SL1 to SL8 and the resist composition RF1 of the Comparative Example in Table 8 was respectively formed thereon by spin-coating and prebaking. The prebaking was performed at 120° C. for 60 seconds, and each sample wafer, having a resist film thickness of 130 nm, was obtained.

Subsequently, regarding SL1 to SL8 of the Examples, by using an ArF immersion exposure apparatus, a 40 nm half-pitch line-and-space pattern formed in a binary reticle was exposed with a lens numerical aperture of 1.35 NA under a constant exposure condition of 25 mJ/cm². Subsequently, each of the exposed wafers was subjected to a PEB (Post Exposure Bake) treatment on a hot plate at 90° C. for 90 seconds. Then, a hot plate baking treatment was performed at 150° C. for 30 seconds as a hard bake.

Subsequently, regarding SL1 to SL8 of the Examples, the exposed portions were etched back under conditions of gas plasma containing oxygen gas, and the resist pattern was separated. In this event, the dry etching conditions were as follows.
Chamber pressure: 30 mT
RF-power (upper portion): 200 W
RF-power (lower portion): 100 W
O₂ gas flow rate: 20 sccm
N₂ gas flow rate: 290 sccm
Etching time: 6 seconds

Meanwhile, regarding the development in the Comparative Example, development with 2.38% TMAH was performed for 15 seconds, then, washing with deionized water was performed for 25 seconds, and subsequently, spin-drying was performed to produce a wafer with a resist pattern.

Subsequently, the wafers of the Examples and the wafer of the Comparative Example were respectively etched under the following dry etching conditions to transfer the pattern to the Si-containing antireflective film of the underlying multilayer.
Chamber pressure: 50 mT
RF-power (upper portion): 500 W
RF-power (lower portion): 300 W
CF₄ gas flow rate: 150 sccm
CHF₃ gas flow rate: 50 sccm
Etching time: 10 seconds

The opening of the Si-containing antireflective film was measured using a low acceleration voltage CD-SEM. The results are shown in Table 9.

Subsequently, while using the pattern transferred to the Si-containing antireflective film as a mask, the pattern was transferred to the coating-type carbon film underneath by etching. The etching conditions in this event were as follows.
Chamber pressure: 30 mT
RF-power (upper portion): 200 W
RF-power (lower portion): 100 W
O₂ gas flow rate: 30 sccm
N₂ gas flow rate: 270 sccm
Etching time: 15 seconds

The space size of the coating-type carbon film was measured using a low acceleration voltage CD-SEM (space size measurement). In addition, the opening of the coating-type carbon film was measured using a low acceleration voltage CD-SEM. The results are shown in Table 9.

TABLE 9

| | | | | | Remaining | | | |
|---|---|---|---|---|---|---|---|---|
| | | | Remaining | Remaining | film | | | |
| | | Remaining | film | film | in | Si- | | |
| | | film | in | in | unexposed | containing | Coating- | |
| | | in | unexposed | exposed | portions | anti- | type | Coating- |
| | Remaining | exposed | portions | portions | after | reflective | carbon | type |
| | film | portions | after | after | dry | film | film | carbon |
| | before | after | hard | hard | develop- | opening | opening | film |
| Sample | exposure | PEB | bake | bake | ment | CD | CD | LWR |
| name | nm | nm | nm | nm | nm | nm | nm | nm |
| R41 | 130 | 130 | 120 | 50 | 95 | 40 | 53 | 2.0 |
| R42 | 130 | 130 | 120 | 53 | 93 | 40 | 42 | 2.1 |
| R43 | 130 | 130 | 120 | 57 | 90 | 40 | 41 | 2.2 |
| R44 | 130 | 130 | 120 | 61 | 75 | 40 | 40 | 2.9 |
| R45 | 130 | 130 | 120 | 65 | 64 | 50 | 50 | 4.1 |
| R46 | 130 | 130 | 120 | 71 | 52 | 67 | 67 | 5.6 |
| R47 | 130 | 130 | 120 | 77 | 45 | 77 | 77 | 7.5 |
| R48 | 130 | 130 | 120 | 105 | 35 | 80 | 80 | 7.5 |
| RF1 | 130 | 130 | Not | Not | Not | 40 | 40 | 2.6 |
| | | | measured | measured | measured | | | |

In the Examples (R41 to R48), where the protection rate was 10% to 100%, etching transfer to the coating-type carbon film, being the multilayer underlayer, was observed. Furthermore, in the Examples of the resist compositions (R41 to R43) where substitution (protection) with an acid-labile group having 9 carbon atoms was performed at 80% to 100%, better LWR (Line Width Roughness) was exhibited compared to the Comparative Example (RF1).

In the Examples of the resist composition (R44 to R48) where the protection rate was less than 80%, phenomena of an increase in the resist size and an increase in roughness were observed, but the results are improved by optimizing the mask bias of the reticle and etching conditions in each Example.

The present description includes the following embodiments.
[1]: A patterning process comprising the steps of:
   forming a multilayer on a substrate to be processed;
   forming a resist upper layer film by using a positive chemically-amplified resist composition for ArF excimer containing, at least, a base polymer having a (meth)acrylic structure substituted with an acid-labile group, a photo-acid generator, a quencher having a function of controlling acid diffusion, and an organic solvent;
   removing the acid-labile group in an exposed portion of the resist upper layer film by exposure and a post-exposure bake;
   performing a hard bake at a higher temperature and for a shorter time than the post-exposure bake to allow the removed acid-labile group to volatilize out of the resist upper layer film and cause a difference in a number of carbon atoms between an unexposed portion and the exposed portion;
   removing the resist upper layer film in the exposed portion with a gas plasma containing oxygen by dry development to separate a pattern; and
   transferring the pattern of the resist upper layer film to the multilayer underneath by etching.
[2]: The patterning process according to [1], wherein the base polymer has a (meth)acrylic structure in which a rate of substitution with the acid-labile group is 80% to 100% and the acid-labile group has 4 to 9 carbon atoms.
[3]: The patterning process according to [1] or [2], wherein the base polymer does not have a lactone structure.
[4]: The patterning process according to any one of [1] to [3], wherein the post-exposure bake is performed at 80° C. to 120° C. for 40 seconds to 120 seconds, and the hard bake is performed at 130° C. or higher for less than 40 seconds.
[5]: The patterning process according to any one of [1] to [4], wherein the resist composition further contains a surfactant that functions as a top coat for ArF immersion exposure, or the patterning process further comprises a step of applying and forming a top coat before the exposure.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A patterning process comprising the steps of:
forming a multilayer on a substrate to be processed;
forming a resist upper layer film by using a positive chemically-amplified resist composition for ArF excimer containing, at least, a base polymer having a (meth)acrylic structure substituted with an acid-labile group, a photo-acid generator, a quencher having a function of controlling acid diffusion, and an organic solvent;
removing the acid-labile group in an exposed portion of the resist upper layer film by exposure and a post-exposure bake;
performing a hard bake at a higher temperature and for a shorter time than the post-exposure bake to allow the removed acid-labile group to volatilize out of the resist upper layer film and cause a difference in a number of carbon atoms between an unexposed portion and the exposed portion;
removing the resist upper layer film in the exposed portion with a gas plasma containing oxygen by dry development to separate a pattern; and
transferring the pattern of the resist upper layer film to the multilayer underneath by etching.

2. The patterning process according to claim 1, wherein the base polymer has a (meth)acrylic structure in which a rate of substitution with the acid-labile group is 80% to 100% and the acid-labile group has 4 to 9 carbon atoms.

3. The patterning process according to claim 1, wherein the base polymer does not have a lactone structure.

4. The patterning process according to claim 2, wherein the base polymer does not have a lactone structure.

5. The patterning process according to claim 1, wherein the post-exposure bake is performed at 80° C. to 120° C. for 40 seconds to 120 seconds, and the hard bake is performed at 130° C. or higher for less than 40 seconds.

6. The patterning process according to claim 2, wherein the post-exposure bake is performed at 80° C. to 120° C. for 40 seconds to 120 seconds, and the hard bake is performed at 130° C. or higher for less than 40 seconds.

7. The patterning process according to claim 3, wherein the post-exposure bake is performed at 80° C. to 120° C. for 40 seconds to 120 seconds, and the hard bake is performed at 130° C. or higher for less than 40 seconds.

8. The patterning process according to claim 4, wherein the post-exposure bake is performed at 80° C. to 120° C. for 40 seconds to 120 seconds, and the hard bake is performed at 130° C. or higher for less than 40 seconds.

9. The patterning process according to claim 1, wherein the resist composition further contains a surfactant that functions as a top coat for ArF immersion exposure, or the patterning process further comprises a step of applying and forming a top coat before the exposure.

10. The patterning process according to claim 2, wherein the resist composition further contains a surfactant that functions as a top coat for ArF immersion exposure, or the patterning process further comprises a step of applying and forming a top coat before the exposure.

11. The patterning process according to claim 3, wherein the resist composition further contains a surfactant that functions as a top coat for ArF immersion exposure, or the patterning process further comprises a step of applying and forming a top coat before the exposure.

12. The patterning process according to claim 4, wherein the resist composition further contains a surfactant that functions as a top coat for ArF immersion exposure, or the patterning process further comprises a step of applying and forming a top coat before the exposure.

13. The patterning process according to claim 5, wherein the resist composition further contains a surfactant that functions as a top coat for ArF immersion exposure, or the patterning process further comprises a step of applying and forming a top coat before the exposure.

14. The patterning process according to claim 6, wherein the resist composition further contains a surfactant that functions as a top coat for ArF immersion exposure, or the patterning process further comprises a step of applying and forming a top coat before the exposure.

15. The patterning process according to claim 7, wherein the resist composition further contains a surfactant that functions as a top coat for ArF immersion exposure, or the patterning process further comprises a step of applying and forming a top coat before the exposure.

16. The patterning process according to claim 8, wherein the resist composition further contains a surfactant that functions as a top coat for ArF immersion exposure, or the patterning process further comprises a step of applying and forming a top coat before the exposure.
